(19) United States
(12) Patent Application Publication
(10) Pub. No.: US 2026/0261246 A1
(43) Pub. Date: Sep. 3, 2026

(54) LOW VOLTAGE OUTPUT STAGE DESIGNS FOR AMPLIFIERS

(71) Applicant: Texas Instruments Incorporated, Dallas, TX (US)

(72) Inventors: Vivek Varier, Tucson, AZ (US); Srinivas K. Pulijala, Tucson, AZ (US)

(21) Appl. No.: 19/067,454

(22) Filed: Feb. 28, 2025

(51) Int. Cl. H03F 3/45

(52) U.S. Cl. CPC H03F 3/45076; H03F 2200/03; H03F 2200/513

(57) ABSTRACT

An example apparatus includes an input stage; current mirror circuitry, the first terminal coupled to the input stage; a first transistor, the first current terminal of the first transistor coupled to the current mirror circuitry, the second current terminal of the first transistor coupled to the input stage; a second transistor, the first current terminal of the second transistor coupled to the first transistor and the current mirror circuitry, the second current terminal of the second transistor coupled to the second transistor; a third transistor, the first current terminal of the third transistor coupled to the second transistor, the second current terminal of the third transistor coupled to a common terminal; and a fourth transistor, the first current terminal of the fourth transistor coupled to a supply terminal, the control terminal of the fourth transistor coupled to the second transistor and the third transistor.

### TECHNICAL FIELD

This description relates generally to amplifiers, and, more particularly, to low voltage output stage designs for amplifiers.

### BACKGROUND

Power amplifiers can be implemented in computing devices, such as a laptop, a tablet, a cell phone, vehicles, an audio device, a sound system, an amplifier system, a speaker system, headphones, robotic systems, direct current (DC) driving circuitry, haptic feedback systems, motor systems, antenna systems, etc. Amplifiers amply a signal into a larger signal that can be used to drive additional circuitry (e.g., motors, speakers, etc.).

### SUMMARY

For low voltage output stage designs for amplifiers, an example apparatus includes an input stage having a first output and a second output; current mirror circuitry having a first terminal and a second terminal, the first terminal coupled to the first output of the input stage; a first transistor having a first current terminal and a second current terminal, the first current terminal of the first transistor coupled to the second terminal of the current mirror circuitry, the second current terminal of the first transistor coupled to the second output of the input stage; a second transistor having a first current terminal, a second current terminal, and a control terminal, the first current terminal of the second transistor coupled to the first current terminal of the first transistor and the second terminal of the current mirror circuitry, the second current terminal of the second transistor coupled to the control terminal of the second transistor; a third transistor having a first current terminal and a second current terminal, the first current terminal of the third transistor coupled to the second current terminal and the control terminal of the second transistor, the second current terminal of the third transistor coupled to a common terminal; a fourth transistor having a first current terminal, a second current terminal, and a control terminal, the first current terminal of the fourth transistor coupled to a supply terminal, the control terminal of the fourth transistor coupled to the first current terminal and the control terminal of the second transistor and the first current terminal of the third transistor; and a fifth transistor having a first current terminal and a second current terminal, the first current terminal of the fifth transistor coupled to the second current terminal of the fourth transistor, the second current terminal of the fifth transistor coupled to the common terminal. Other examples are described.

For low voltage output stage designs for amplifiers, an example apparatus includes an input stage having a first output and a second output; current mirror circuitry having a first terminal, a second terminal, and a third terminal, the first terminal coupled to the first output of the input stage; a first transistor having a first current terminal, a second current terminal, and a control terminal, the first current terminal of the first transistor coupled to the second terminal and the third terminal of the current mirror circuitry, the second current terminal of the first transistor coupled to the second output of the input stage; an amplifier having a first input, a second input, and an output, the second input of the amplifier coupled to the second current terminal of the first transistor, the output of the amplifier coupled to the control terminal of the first transistor; a second transistor having a first current terminal and a second current terminal, the first current terminal of the second transistor coupled to the second current terminal of the first transistor, the second input of the amplifier, and the second output of the input stage, the second current terminal of the second transistor coupled to a common terminal; a third transistor having a first current terminal, a second current terminal and a control terminal, the second current terminal of the third transistor coupled to the common terminal, the control terminal of the third transistor coupled to the second current terminal of the first transistor, the second input of the amplifier, the first current terminal of the second transistor and the second output of the input stage; and a fourth transistor having a first current terminal and a second current terminal, the first current terminal of the fourth transistor coupled to a supply terminal, the second current terminal of the fourth transistor coupled to the first current terminal of the third transistor. Other examples are described.

For low voltage output stage designs for amplifiers, an example apparatus includes an input stage having a first output and a second output; current mirror circuitry having a first terminal, a second terminal, and a third terminal, the first terminal coupled to the first output of the input stage; a first transistor having a first current terminal and a second current terminal, the first current terminal of the first transistor coupled to the second terminal of the current mirror circuitry, the second current terminal of the first transistor coupled to the second output of the input stage; a second transistor having a first current terminal, a second current terminal, and a control terminal, the first current terminal of the second transistor coupled to the third terminal of the current mirror circuitry and the control terminal of the second transistor, the second current terminal of the second transistor coupled to the second current terminal of the first transistor and the second output of the input stage; a third transistor having a first current terminal and a second current terminal, the first current terminal of the third transistor coupled to the second current terminals of the first and second transistors and the second output of the input stage, the second current terminal of the third transistor coupled to a common terminal; a fourth transistor having a first current terminal, a second current terminal and a control terminal, the second current terminal of the fourth transistor coupled to the common terminal, the control terminal of the fourth transistor coupled to the first current terminal and the control terminal of the second transistor and the third terminal of the current mirror circuitry; and a fifth transistor having a first current terminal and a second current terminal, the first current terminal of the fifth transistor coupled to a supply terminal, the second current terminal of the fifth transistor coupled to the first current terminal of the fourth transistor. Other examples are described.

### BRIEF DESCRIPTION OF THE DRAWINGS

FIG. 1 is an example computing device implementing an amplifier output stage in conjunction with examples described herein.

FIG. 2 is a circuit diagram of an example implementation of the input stage and the output stage of the amplifier of FIG. 1.

FIG. 3 is an alternative circuit diagram of an example implementation of the input stage and the output stage of the amplifier of FIG. 2.

FIG. 4 is a circuit diagram of an example implementation of the input stage and the output stage of FIG. 2 in a quiescent state.

FIG. 5 is a circuit diagram of an example implementation of the input stage and the output stage of FIG. 2 in a sourcing state.

FIG. 6 is a circuit diagram of an example implementation of the input stage and the output stage of FIG. 2 in a sinking state.

FIG. 7 illustrates a flowchart representative of an example method or example operations that may be executed, instantiated, or performed by the amplifier of FIGS. 2-6.

FIG. 8 is an example current graph illustrating the class AB operation of the output stage of FIGS. 2 and 3 during sourcing, sinking, and quiescent states.

FIG. 9 is an example current graph illustrating the class AB operation of the output stage of FIGS. 2 and 3 based on different supply voltages.

FIG. 10 is an alternative circuit diagram of an example implementation of the input stage and the output stage of the amplifier of FIG. 1.

FIG. 11 is a circuit diagram of an example implementation of the output stage of FIG. 10 in a quiescent state.

FIG. 12 is a circuit diagram of an example implementation of the output stage of FIG. 10 in a sourcing state.

FIG. 13 is a circuit diagram of an example implementation of the output stage of FIG. 10 in a sinking state.

FIG. 14 illustrates a flowchart representative of an example method or example operations that may be executed, instantiated, or performed by the output stage of FIGS. 10-13.

FIG. 15 is an example current graph illustrating the class AB operation of the output stage of FIG. 10 during sourcing, sinking, and quiescent states.

FIG. 16 is an example current graph illustrating the class AB operation of the output stage of FIG. 10 based on different supply voltages.

FIGS. 17A and 17B illustrates a comparison of shoot-through currents in some AB output stages and the AB output stages described in conjunction with examples described herein.

The same reference numbers or other reference designators are used in the drawings to designate the same or similar (functionally or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines or boundaries may be idealized. In reality, the boundaries or lines may be unobservable, blended or irregular.

A power amplifier is an electronic device designed to increase the power of an input signal. Power amplifiers increase the strength of a low-level signal into a high-level signal to drive a load like motors, DC driving circuitry, speakers or headphones, essentially acting as the final stage in an amplification chain delivering a high-power output to directly power external devices. Power amplifiers can be included in audio systems and/or other systems. In audio systems, a power amplifier boosts the power of a pre-amplified signal to produce audible sound through speakers. In other systems, power amplifiers can amplify a weak input signal to a high power output signal that can drive other circuitry.

Power amplifiers may include, but are not limited to, class A amplifiers, class B amplifiers, and class AB amplifiers. A Class A amplifier is typically the least efficient but has the highest sound fidelity. A Class B amplifier is more efficient than a class A amplifier but includes more distortion than the class A amplifier. A Class AB amplifier combines elements of Class A and Class B amplifiers. Class AB amplifiers can achieve high efficiency like a Class B amplifier while minimizing distortion like a Class A amplifier by strategically biasing the output transistors so they conduct slightly even as the load current is zero or near zero. Class AB amplifiers eliminate or minimize the “crossover distortion” that occurs in pure Class B amplifiers. Accordingly, Class AB amplifiers can be used audio applications where both power and fidelity are important to a user or manufacturer, offering a good balance between efficiency and low distortion. To achieve the balance of efficiency and low distortion, AB amplifiers bias the output transistors so that they partially conduct to draw a small current as the load current is close to zero amperes (amps), the point where class B amplifiers introduce non-linearities. Although partially conducting the output transistors draws power, partially conducting the output transistors avoids the crossover distortion associated with class B amplifiers by avoiding the non-linearities as the load current is close to zero amps. An ideal class AB output amplifier has particular AB properties, such as causing the output transistors to draw a small amount of current as the load current is near zero amps, having a controlled current through the partially conducting transistor during sourcing/sinking, minimizing shoot-through issues, etc.

Lowering power requirements of systems preserves battery live and/or prolongs the life of a product. Accordingly, there is an industry desire to reduce the power supply from 1.4 volts (V) to 1 V or less to increase battery lift, prolong product life, etc. Accordingly, the minimum power supply of some class AB amplifiers may be too high due to the inherent headroom challenges that limit scaling to lower voltage levels. For example, within an AB amplifier, the path (also referred to as a critical path) from the supply voltage (VDD) to the ground voltage (AVSS) is limited by the sum of the voltage drops across components connecting the supply voltage to the ground voltage. For some AB amplifiers, the minimum power is at least 1.4 V. Examples described herein provide an AB amplifier and an AB/A hybrid amplifier that operates at or below 1 V, thereby providing additional power savings without sacrificing class AB properties. Also, the example amplifiers described herein minimize shoot-through issues associated with some power amplifiers.

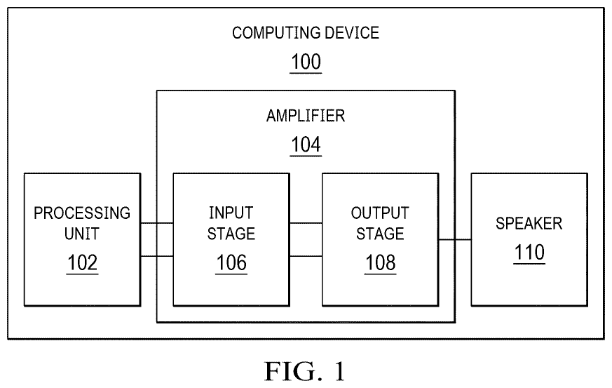

FIG. 1 illustrates an example computing device 100. The computing device 100 of FIG. 1 includes an example processing unit 102, an example amplifier 104, which includes an example input stage 106 and an example output stage 108, and an example speaker 110. The computing device 100 of FIG. 1 may be a computer, a laptop, a television, a cell phone, a tablet, a monitor, a receiver, a set-top-box, or any other type of computing device. Although the example computing device 100 includes all of the components, one or more of the components may be implemented in one or more external devices. For example, the computing device 100 may be implemented in a first device, such as a cell phone, laptop, etc., and the amplifier 104 and the speaker 110 may be implemented in a second device, such as headphones, wireless speakers, etc. Also, one or more of the components of the computing device 100 may be removed or combined. Also, additional components may be added to the computing device 100. Although FIG. 1 is described in conjunction with the output stage 108 driving the speaker 110, examples disclosed herein can be utilized to amplify a signal to drive any circuitry.

The processing unit 102 of FIG. 1 performs one or more functions based on applications or instructions. The processing unit 102 may be a central processing unit, a graphical processing unit, a digital signal processor, a microprocessor, a hard drive, a controller, a microcontroller, or any other processing unit. The processing unit 102 may execute or instantiate instructions or applications. The instructions or applications may generate or output an audio signal to the amplifier 104 to be played via the example speaker 110. The processing unit 102 is coupled to the amplifier 104.

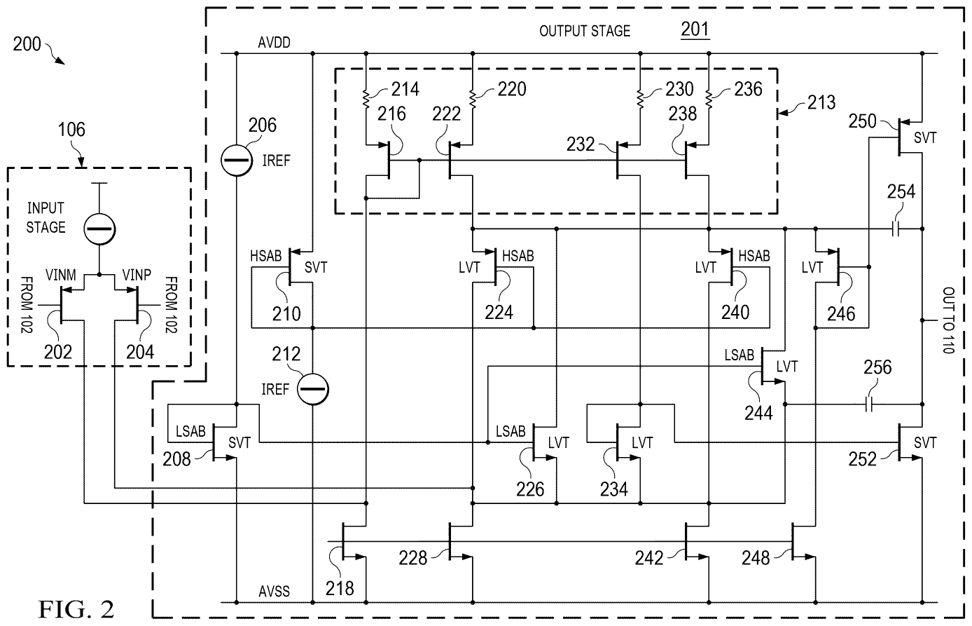

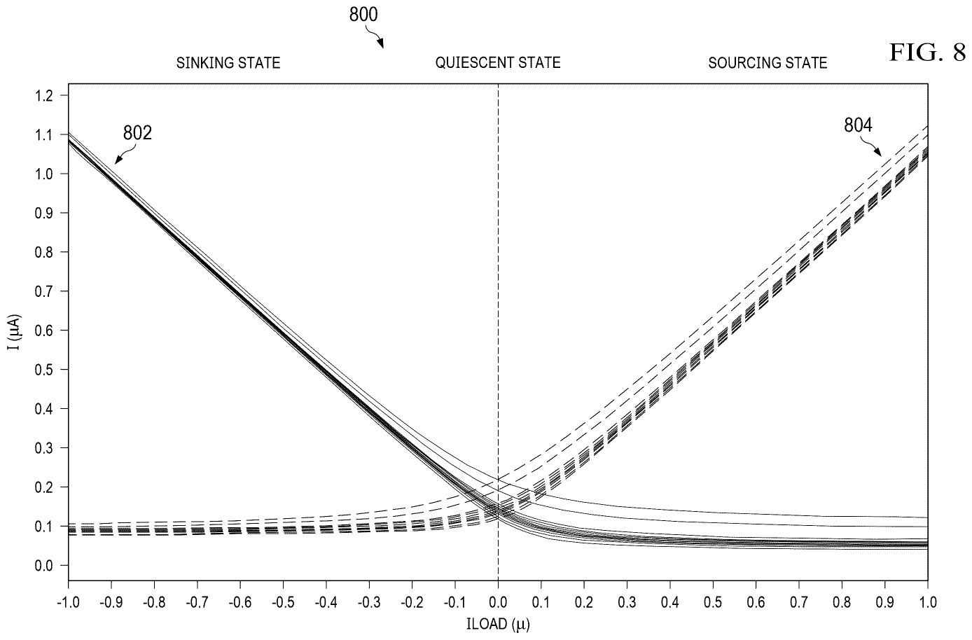

The amplifier 104 of FIG. 1 includes a first input and a second input coupled to the processing unit 102 and an output coupled to the speaker 110. The amplifier 104 amplifies the audio signal output by the processing unit 102 to a particular level so that the audio corresponding to the audio signal can be properly output by the speaker 112. In some examples, the amplifier 104 is implemented to operate as a class AB amplifier, as further described below in conjunction with FIGS. 2-5. In some examples, the amplifier 104 is implemented to operate as a class AB/class A hybrid amplifier, as further described below in conjunction with FIGS. 8-11. The input stage 106 of the amplifier 104 amplifies the input signals from the processing unit 102 to a level that can be processed by the output stage 108. The output stage 108 of the amplifier 104 includes a complementary pair of transistors that handle the negative positive half and negative have of the input signals for sourcing or sinking a load with the amplified output signal. The input stage 106 and the output stage 108 are further described below in conjunction with FIGS. 2-5 and 8-11. A first input and second input of the input stage 106 is coupled to the processing unit 102. A first output and second output of the input stage 106 is coupled to the output stage 108. A first input and second input of the output stage 108 is coupled to the input stage 106. An output of the output stage 108 is coupled to the speaker 110.

The speaker 110 of FIG. 1 plays audio based on a received audio signal from the amplifier 104. For example, if the audio signal corresponds to music or speech, the speaker 110 converts the audio signal into the music or speech and output the music or speech to a user. The speaker 110 includes an input coupled to the output stage 108 of the amplifier 104.

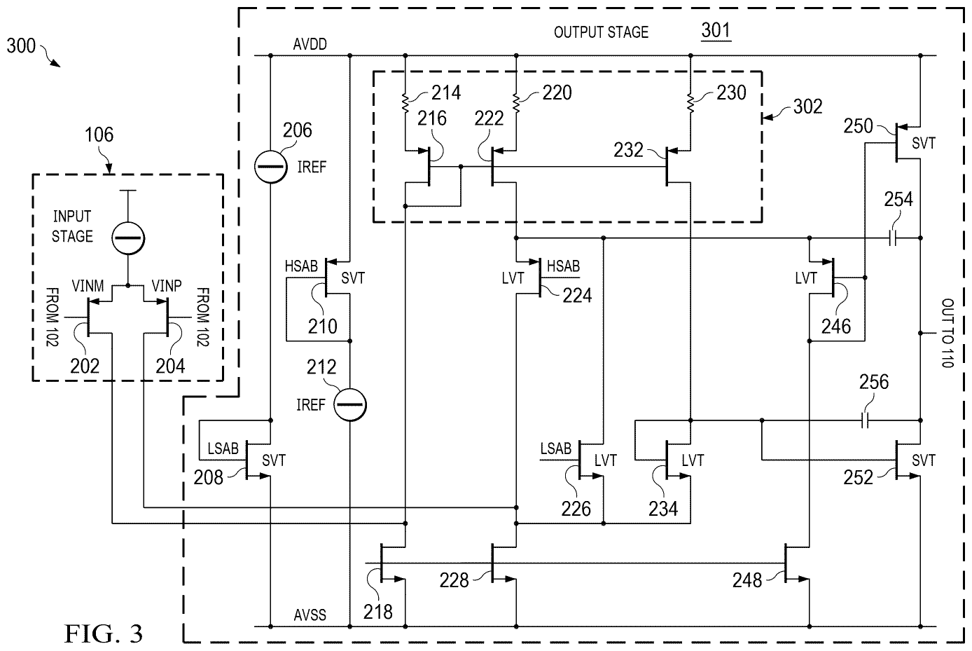

FIG. 2 is an example circuit implementation of an example amplifier 200 including the input stage 106 of FIG. 1 and an example output stage 201. The amplifier 200 can be used to implement the amplifier 104 of FIG. 1 and the output stage 201 can be used to implement the output stage 108 of FIG. 1. The input stage 106 of FIG. 2 includes example transistors 202, 204. The output stage 201 of FIG. 2 includes example current sources 206, 212, example transistors 208, 210, 216, 218, 222, 224, 226, 228, 232, 234, 238, 240, 242, 244, 246, 248, 250, 252, example current mirror circuitry 213, example resistors 214, 220, 230, 236, and example capacitors 254, 256. Operation of the output stage 201 in different states is further described below in conjunction with FIGS. 3-5.

The transistor 202 of FIG. 2 operates as a voltage controlled current device to allow or block current from entering the output stage 201 based on the output voltage(s) from the processor unit 102. The transistor 202 includes a first current terminal (a source terminal), a second current terminal (a drain terminal), and a control terminal (a gate terminal). The first current terminal of the transistor 202 is coupled to a current source or a supply voltage. The second current terminal of the transistor 202 is coupled to the second current terminal of the transistor 216, the control terminals of the transistors 216, 222, 232, 238, and the first current terminal of the transistor 218 of the output stage 201. The control terminal of the transistor 202 is coupled to the processor unit 102. The transistor 202 is a p-channel metal oxide semiconductor field effect transistor (P-channel MOSFET, PMOS transistor, etc.). However, the transistor 202 may be another type of transistor.

The transistor 204 of FIG. 2 operates as a voltage controlled current device to allow or block current from entering the output stage 201 based on the output voltage(s) from the processor unit 102. The transistor 204 includes a first current terminal (a source terminal), a second current terminal (a drain terminal), and a control terminal (a gate terminal). The first current terminal of the transistor 204 is coupled to a current source or a supply voltage. The second current terminal of the transistor 204 is coupled to the second current terminals of the transistors 224, 226, 234, 224 and the first terminal of the capacitor 256. The control terminal of the transistor 204 is coupled to the processor unit 102. The transistor 204 is a PMOS transistor. However, the transistor 204 may be another type of transistor.

The current source 206 of FIG. 2 provides a preset amount of current (a reference current IR) toward the transistor 208. The current source 206 includes a first terminal and a second terminal. The first terminal of the current source 206 is coupled to the supply voltage terminal (AVDD). The second terminal of the current source 206 is coupled to the first current terminal of the transistor 208, the control terminal of the transistor 208 and the control terminals of the transistors 226, 244.

The transistor 208 of FIG. 2 is a diode connected transistor to operate as a diode. The transistor 208 includes a first current terminal (a drain terminal), a second current terminal (a source terminal), and a control terminal (a gate terminal). The first current terminal of the transistor 208 is coupled to the second terminal of the current source 206 and the gate terminals of the transistors 208, 226, 244. The second current terminal of the transistor 208 is coupled to a common terminal, such as ground, AVSS, etc. The control terminal of the transistor 208 is coupled to the second terminal of the current source 206, the first current terminal of the transistor 208, and the gate terminals of the transistors 226, 244. The transistor 208 is an n-channel MOSFET (NMOS transistor). However, the transistor 208 may be another type of transistor. Because the transistor 208 is configured as a diode-connected transistor, the transistor 208 creates a voltage drop (0.7 Volts (V), for example) across the first current terminal and the second current terminal of the transistor 208. The transistor 208 corresponds to a standard threshold voltage (SVT).

The transistor 210 of FIG. 2 is a diode connected transistor to operate as a diode. The transistor 210 includes a first current terminal (a source terminal), a second current terminal (a drain terminal), and a control terminal (a gate terminal). The first current terminal of the transistor 210 is coupled to the supply voltage terminal (AVDD). The second current terminal of the transistor 210 is coupled to the gate terminals of the transistors 210, 224, 240 and the first terminal of the current source 212. The control terminal of the transistor 210 is coupled to the second current terminal of the transistor 210, the gate terminals of the transistors 224, 240 and the first terminal of the current source 212. The transistor 210 is a p-channel MOSFET (PMOS transistor). However, the transistor 210 may be another type of transistor. Because the transistor 210 is configured as a diode-connected transistor, the transistor 210 creates a voltage drop (0.7 Volts (V), for example) across the first current terminal and the second current terminal of the transistor 210. The transistor 210 corresponds to a standard threshold voltage (SVT).

The current source 212 of FIG. 2 provides a preset amount of current (a reference current IREF) from the transistor 210 toward the common terminal (AVSS). The current source 212 includes a first terminal and a second terminal. The first terminal of the current source 212 is coupled the gate terminals of the transistors 210, 224, 240 and the second current terminal of the transistor 210. The second terminal of the current source 212 is coupled to a common terminal (ground or AVSS).

The current mirror circuitry 213 of FIG. 2 includes the resistors 214, 220, 230, 236 and the transistors 216, 222, 232, 238. The resistor 214 of FIG. 2 includes a first terminal and a second terminal. The first terminal of the resistor 214 is coupled to the supply voltage terminal (AVDD). The second terminal of the resistor 214 is coupled to the first current terminal of the transistor 216.

The transistor 216 of FIG. 2 operates as a voltage controlled current device to allow or block current between the two current terminals of the transistor 216 based on the voltage at the control terminal of the transistor 216. The transistor 216 includes a first current terminal (a source terminal), a second current terminal (a drain terminal), and a control terminal (a gate terminal). The first current terminal of the transistor 216 is coupled to the second terminal of the resistor 214. The second current terminal of the transistor 216 is coupled to the gates of the transistors 216, 222, 232, 238, the first current terminal of the transistor 218, and the second current terminal of the transistor 202. The control terminal of the transistor 216 is coupled to the second current terminal of the transistor 216, the gates of the transistors 222, 232, 238, the first current terminal of the transistor 218, and the second current terminal of the transistor 202. The transistor 216 is a PMOS transistor. However, the transistor 216 may be another type of transistor.

The transistor 218 of FIG. 2 operates as a voltage controlled current device to allow or block current between the two current terminals of the transistor 218 based on the voltage at the control terminal of the transistor 218. The transistor 218 includes a first current terminal (a drain terminal), a second current terminal (a source terminal), and a control terminal (a gate terminal). The first current terminal of the transistor 218 is coupled to the gates of the transistors 216, 222, 232, 238, the second current terminal of the transistor 216, and the second current terminal of the transistor 202. The second current terminal is coupled to the common terminal (AVSS). The control terminal of the transistor 218 is coupled to the gates of the transistors 228, 242, 248 and bias circuitry (not shown). The bias circuitry may include a diode connected transistor whose first current terminal is coupled to a current source that is coupled to the supply terminal (AVDD) and whose second current terminal is coupled to the common terminal (AVSS). The transistor 218 is an NMOS transistor. However, the transistor 218 may be another type of transistor.

The resistor 220 of FIG. 2 includes a first terminal and a second terminal. The first terminal of the resistor 220 is coupled to the supply voltage terminal (AVDD). The second terminal of the resistor 220 is coupled to the first current terminal of the transistor 222.

The transistor 222 of FIG. 2 operates as a voltage controlled current device to allow or block current between the two current terminals of the transistor 222 based on the voltage at the control terminal of the transistor 222. The transistor 222 includes a first current terminal (a source terminal), a second current terminal (a drain terminal), and a control terminal (a gate terminal). The first current terminal of the transistor 222 is coupled to the second terminal of the resistor 220. The second current terminal of the transistor 222 is coupled to the first current terminals of the transistors 224, 226, 240, 244, 246, the second current terminal of the transistor 238, and the first terminal of the capacitor 254. The control terminal of the transistor 222 is coupled to the second current terminal of the transistor 222, the gates of the transistors 216, 232, 238, the first current terminal of the transistor 218, and the second current terminal of the transistor 202. The transistor 222 is a PMOS transistor. However, the transistor 222 may be another type of transistor.

The transistor 224 of FIG. 2 operates as a voltage controlled current device to allow or block current between the two current terminals of the transistor 224 based on the voltage at the control terminal of the transistor 224. The transistor 224 includes a first current terminal (a source terminal), a second current terminal (a drain terminal), and a control terminal (a gate terminal). The first current terminal of the transistor 224 is coupled to the second current terminal of the transistor 222, the first current terminals of the transistors 226, 240, 244, 246, and the first terminal of the capacitor 254. The second current terminal of the transistor 224 is coupled to the first current terminals of the transistors 228, 242, and the second current terminals of the transistors 226, 234, 240, 244, and the first terminal of the capacitor 256. The control terminal of the transistor 224 is coupled to the control terminals of the transistors 210, 240, the second current terminal of the transistor 210 and the first terminal of the current source 212. The transistor 224 is a PMOS transistor. However, the transistor 224 may be another type of transistor. The transistor 224 corresponds to a low threshold voltage (LVT).

The transistor 226 of FIG. 2 operates as a voltage controlled current device to allow or block current between the two current terminals of the transistor 226 based on the voltage at the control terminal of the transistor 226. The transistor 226 includes a first current terminal (a drain terminal), a second current terminal (a source terminal), and a control terminal (a gate terminal). The first current terminal of the transistor 226 is coupled to the second current terminal of the transistor 222, the first current terminals of the transistors 224, 240, 244, 246, and the first terminal of the capacitor 254. The second current terminal of the transistor 226 is coupled to the first current terminal of the transistors 228, 242, the second current terminals of the transistors 204, 224, 234, 240, 244, and the first terminal of the capacitor 256. The control terminal of the transistor 226 is coupled to the control terminals of the transistors 208, 244, the first current terminal of the 208 and the second terminal of the current source 206. The transistor 226 is an NMOS transistor. However, the transistor 226 may be another type of transistor. The transistor 226 corresponds to a low threshold voltage (LVT).

The transistor 228 of FIG. 2 operates as a voltage controlled current device to allow or block current between the two current terminals of the transistor 228 based on the voltage at the control terminal of the transistor 228. The transistor 228 includes a first current terminal (a drain terminal), a second current terminal (a source terminal), and a control terminal (a gate terminal). The first current terminal of the transistors 228 is coupled to the second current terminals of the transistors 204, 224, 226, 234, 244, the first terminal of the transistor 242, and the first terminal of the capacitor 256. The second current terminal of the transistor 228 is coupled to the common terminal (AVSS). The control terminal of the transistor 228 is coupled to the control terminals of the transistors 218, 242, 248 and to bias circuitry. The transistor 228 is an NMOS transistor. However, the transistor 228 may be another type of transistor.

The resistor 230 of FIG. 2 includes a first terminal and a second terminal. The first terminal of the resistor 230 is coupled to the supply voltage terminal (AVDD). The second terminal of the resistor 230 is coupled to the first current terminal of the transistor 232.

The transistor 232 of FIG. 2 operates as a voltage controlled current device to allow or block current between the two current terminals of the transistor 232 based on the voltage at the control terminal of the transistor 232. The transistor 232 includes a first current terminal (a source terminal), a second current terminal (a drain terminal), and a control terminal (a gate terminal). The first current terminal of the transistor 232 is coupled to the second terminal of the resistor 230. The second current terminal of the transistor 232 is coupled to the first current terminal and the control terminal of the transistor 234 and the control terminal of the transistor 252. The control terminal of the transistor 232 is coupled to the second current terminal of the transistor 232, the gates of the transistors 216, 222, 238, the first current terminal of the transistor 218, and the second current terminal of the transistor 202. The transistor 232 is a PMOS transistor. However, the transistor 232 may be another type of transistor.

The transistor 234 of FIG. 2 is a diode connected transistor that operates as a voltage controlled current device to allow or block current between the two current terminals of the transistor 234 based on the voltage at the control terminal of the transistor 234. The transistor 234 includes a first current terminal (a drain terminal), a second current terminal (a source terminal), and a control terminal (a gate terminal). The first current terminal of the transistor 234 is coupled to the first current terminal of the transistor 232, the control terminal of the transistor 234, and the control terminal of the transistor 252. The second current terminal of the transistor 234 is coupled to the second current terminals of the transistors 204, 224, 226, 240, 244, the first current terminals of transistors 228, 242, and the first terminal of the capacitor 256. The control terminal of the transistor 234 is coupled to the first current terminal of the transistor 232, the first current terminal of the transistor 234, and the control terminal of the transistor 252. The transistor 234 is a PMOS transistor. However, the transistor 234 may be another type of transistor. The transistor 234 corresponds to a low threshold voltage (LVT).

The resistor 236 of FIG. 2 includes a first terminal and a second terminal. The first terminal of the resistor 236 is coupled to the supply voltage terminal (AVDD). The second terminal of the resistor 236 is coupled to the first current terminal of the transistor 238.

The transistor 238 of FIG. 2 operates as a voltage controlled current device to allow or block current between the two current terminals of the transistor 238 based on the voltage at the control terminal of the transistor 238. The transistor 238 includes a first current terminal (a source terminal), a second current terminal (a drain terminal), and a control terminal (a gate terminal). The first current terminal of the transistor 238 is coupled to the second terminal of the resistor 236. The second current terminal of the transistor 238 is coupled to the first current terminals of the transistors 224, 226, 240, 244, 246, the second current terminal of the transistor 222, and the first terminal of the capacitor 254. The control terminal of the transistor 238 is coupled to the second current terminal of the transistor 222, the gates of the transistors 216, 222, 232, the first current terminal of the transistor 218, and the second current terminal of the transistor 202. The transistor 238 is a PMOS transistor. However, the transistor 238 may be another type of transistor.

The transistor 240 of FIG. 2 operates as a voltage controlled current device to allow or block current between the two current terminals of the transistor 240 based on the voltage at the control terminal of the transistor 240. The transistor 240 includes a first current terminal (a source terminal), a second current terminal (a drain terminal), and a control terminal (a gate terminal). The first current terminal of the transistor 240 is coupled to the second current terminal of the transistor 222, the first current terminals of the transistors 224, 226, 244, 246, and the first terminal of the capacitor 254. The second current terminal of the transistor 240 is coupled to the first current terminals of the transistors 228, 242, the second current terminals of the transistors 204, 224, 226, 234, 244, and the first terminal of the capacitor 256. The control terminal of the transistor 240 is coupled to the control terminals of the transistors 210, 240, the second current terminal of the transistor 210 and the first terminal of the current source 212. The transistor 240 is a PMOS transistor. However, the transistor 240 may be another type of transistor. The transistor 240 corresponds to a low threshold voltage (LVT).

The transistor 242 of FIG. 2 operates as a voltage controlled current device to allow or block current between the two current terminals of the transistor 242 based on the voltage at the control terminal of the transistor 242. The transistor 242 includes a first current terminal (a drain terminal), a second current terminal (a source terminal), and a control terminal (a gate terminal). The first current terminal of the transistors 242 is coupled to the second current terminals of the transistors 204, 224, 226, 234, 240, 244, the first terminal of the transistor 228, and the first terminal of the capacitor 256. The second current terminal of the transistor 242 is coupled to the common terminal (AVSS). The control terminal of the transistor 242 is coupled to the control terminals of the transistors 218, 228, 248 and to bias circuitry. The transistor 242 is an NMOS transistor. However, the transistor 242 may be another type of transistor.

The transistor 244 of FIG. 2 operates as a voltage controlled current device to allow or block current between the two current terminals of the transistor 244 based on the voltage at the control terminal of the transistor 244. The transistor 244 includes a first current terminal (a drain terminal), a second current terminal (a source terminal), and a control terminal (a gate terminal). The first current terminal of the transistor 244 is coupled to the second current terminal of the transistor 222, the first current terminals of the transistors 224, 226, 240, 246, and the first terminal of the capacitor 254. The second current terminal of the transistor 244 is coupled to the second current terminals of the transistors 204, 224, 226, 234, 240, the first current terminals of the transistors 228, 242, and the first terminal of the capacitor 256. The control terminal of the transistor 244 is coupled to the control terminals of the transistors 208, 226, the first current terminal of the transistor 208 and the second terminal of the current source 206. The transistor 244 is an NMOS transistor. However, the transistor 244 may be another type of transistor. The transistor 244 corresponds to a low threshold voltage (LVT).

The transistor 246 of FIG. 2 operates as a diode connected transistor. The transistor 246 includes a first current terminal (a source terminal), a second current terminal (a drain terminal), and a control terminal (a gate terminal). The first current terminal of the transistor 246 is coupled to the second current terminal of the transistor 222, the first current terminals of the transistors 224, 226, 240, 244, and the first terminal of the capacitor 254. The second current terminal of the transistor 246 is coupled to the control terminals of the transistors 246, 250, and the first current terminal of the transistor 248. The control terminal of the transistor 246 is coupled to the control terminal of the transistor 250, the second current terminal of the transistor 246, and the first current terminal of the transistor 248. The transistor 246 is a PMOS transistor. However, the transistor 246 may be another type of transistor. The transistor 246 corresponds to a low threshold voltage (LVT).

The transistor 248 of FIG. 2 operates as a voltage controlled current device to allow or block current between the two current terminals of the transistor 248 based on the voltage at the control terminal of the transistor 248. The transistor 248 includes a first current terminal (a drain terminal), a second current terminal (a source terminal), and a control terminal (a gate terminal). The first current terminal of the transistors 248 is coupled to the control terminals of the transistor 246, 250 and the second current terminal of the transistor 246. The second current terminal of the transistor 248 is coupled to the common terminal (AVSS). The control terminal of the transistor 248 is coupled to the control terminals of the transistors 218, 228, 242 and to bias circuitry. The transistor 248 is an NMOS transistor. However, the transistor 248 may be another type of transistor.

The transistor 250 of FIG. 2 is an output PMOS transistor that operates as a voltage controlled current device to allow to flow current between the two current terminals of the transistor 250 based on the voltage at the control terminal of the transistor 250. The transistor 250 includes a first current terminal (a source terminal), a second current terminal (a drain terminal), and a control terminal (a gate terminal). The first current terminal of the transistor 250 is coupled to the voltage supply terminal (AVDD). The second current terminal of the transistor 250 is coupled to the second terminals of the capacitors 254, 256, the first current source of the transistor 252, and the speaker 110 of FIG. 1. The control terminal of the transistor 250 is coupled to the gate terminal of the transistor 246, the second current terminal of the transistor 246, and the first current terminal of the transistor 248. The transistor 246 is a PMOS transistor. However, the transistor 246 may be another type of transistor. The transistor 250 corresponds to a standard threshold voltage (SVT). The transistor 250 is also referred to as a high side transistor to provide a high voltage (AVDD) or high current to the speaker 110.

The transistor 252 of FIG. 2 is an output NMOS transistor that operates as a voltage controlled current device to allow to flow current between the two current terminals of the transistor 252 based on the voltage at the control terminal of the transistor 252. The transistor 252 includes a first current terminal (a drain terminal), a second current terminal (a drain terminal), and a control terminal (a gate terminal). The first current terminal of the transistor 252 is coupled to the second current terminal of the transistor 250, the second terminals of the capacitors 254, 256, and the speaker 110 of FIG. 1. The second current terminal of the transistor 252 is coupled to common terminal (AVSS). The control terminal of the transistor 252 is coupled to the second current terminal of the transistor 232, the first current terminal of the transistor 234, and the control terminal of the transistor 234. The transistor 252 is an NMOS transistor. However, the transistor 252 may be another type of transistor. The transistor 252 corresponds to a standard threshold voltage (SVT). The transistor 250 is also referred to as a low side transistor to provide/sink a low voltage (AVSS) or low current to the speaker 110. The low voltage may be 0 V or a negative voltage. The low current is a negative current that flows from the speaker 110 to the AVSS terminal.

The capacitor 254 of FIG. 2 is a Miller capacitor that provides frequency compensation. Also, the capacitor 254 corresponds to a slew path to the common terminal, as further described below. The capacitor 254 includes a first terminal and a second terminal. The first terminal of the capacitor 254 is coupled to the second current terminals of the transistors 222, 232, 238 and the first current terminals of the transistors 224, 226, 240, 244, 246. The second terminal of the capacitor 254 is coupled to the second current terminal of the transistor 250, the first current terminal of the transistor 252, the second terminal of the capacitor 254, and the speaker 110.

The capacitor 256 of FIG. 2 is a Miller capacitor that provides frequency compensation. Also, the capacitor 254 corresponds to a slew path to the common terminal, as further described below. The capacitor 256 includes a first terminal and a second terminal. The first terminal of the capacitor 256 is coupled to the second current terminals of the transistors 204, 224, 226, 234, 240, 244 and the first current terminals of the transistors 228, 242. The second terminal of the capacitor 256 is coupled to the second current terminal of the transistor 250, the first current terminal of the transistor 252, the second terminal of the capacitor 254, and the speaker 110. Operation of the amplifier 200 is further described below in conjunction with FIGS. 3-5.

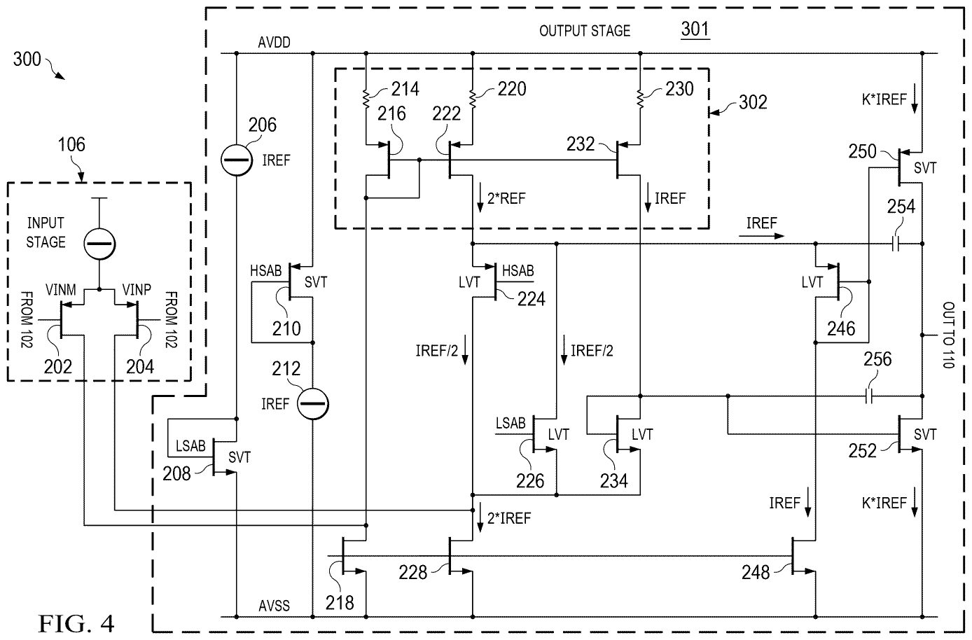

The size of the transistors 216, 228, 234, 238, 246 are twice the size of the transistors 222, 232, 224, 226, 242, 248. This creates different amount of currents that can flow through the transistors, as further described below in conjunction with FIGS. 4-6.

The minimum voltage of the amplifier 200 corresponds to the critical path from AVDD to AVSS. The critical path corresponds to the path from AVDD to AVSS. The minimum voltage needs to be high enough for proper operations of the transistors within the critical path. In the example of FIG. 2, the critical path is from AVDD to the first current terminal of the transistor 250, to the control terminal of the transistor 250, and across the current terminals of the transistor 248 to AVSS. For example, the source-to-gate voltage of the transistor 250 may be close to the threshold voltage (e.g., approximately 0.7 V) and the drain to source saturation voltage (Vdsat) or overdrive voltage of the transistor 248 may be approximately 0.2 V. In such an example, the minimum voltage for the amplifier 200 is 0.9 V, which is the sum of the voltage drops along the critical path.

FIG. 3 is an alternative example circuit implementation of an example amplifier 300 including the input stage 106 of FIG. 1 and an example output stage 301. The amplifier 300 can be used to implement the amplifier 104 of FIG. 1 and the output stage 301 can be used to implement the output stage 108 of FIG. 1. The input stage 106 of FIG. 2 includes the example transistors 202, 204 of FIG. 2. The output stage 301 of FIG. 3 includes the example current sources 206, 212, the example transistors 208, 210, 216, 218, 222, 224, 226, 228, 232, 234, 246, 248, 250, 252, the example resistors 214, 220, 230, and the example capacitors 254, 256 of FIG. 2. FIG. 3 further includes an example current mirror circuitry 302.

The example output stage 301 of FIG. 3 operates in a substantially similar manner as the output stage 201 of FIG. 2. However, the output stage 310 achieves similar results and operation with fewer components. For example, the output stage 310 does not include the resistor 236 and the transistors 238, 240, 242, 243 of FIG. 2. Accordingly, the output stage 301 is a low power class AB output stage power amplifier with less components than in FIG. 2.

In FIG. 3, the size of the transistors 216, 218, 222, 228, 234, 246 are twice the size of the transistors 224, 224, 232, 248. This creates different amounts of currents that can flow through the transistors, as further described below in conjunction with FIGS. 4-6.

FIG. 4 illustrates the current flow through the output stage 301 of FIG. 3 during a quiescent state. A quiescent state is a state which there is no output current load. FIG. 4 includes all the components of FIG. 3. However, FIG. 4 could be described in conjunction with FIG. 2.

As shown in FIG. 4, during a quiescent state, the transistor 248 is biased so that the current IREF flows into the first current source of the transistor 248. The IREF current may be the same amount of current generated by either current source 206, 212. Also, during the quiescent state, the IREF current flows out from the second current terminal of the transistor 232 toward the diode connected transistor 234. The IREF current into the diode connected transistor 234 biases the gate of the transistor 252 at a voltage between 0 and the saturation threshold voltage (Vth), thereby causing the transistor 252 to operate as a resistor. Accordingly, the current through the transistor 252 is K*IREF, where K is a ratio of the size of the transistor 252 to the size of the transistor 208.

Due to the size of the transistor 222, 2*IREF flows out from the second current terminal of the transistor 222, which is split between three paths. The first path is toward the transistor 246, the second path is toward the transistor 226, and the third path is toward the transistor 224. Because the transistor 246 is twice the size of the transistors 224, 226, IREF flows toward the first current terminal of transistor 246 and IREF/2 flows toward the first current terminal of the transistor 226 and the first current terminal of the transistor 224. The IREF current into the diode connected transistor 246 biases the gate of the transistor 250 at a voltage between 0 and the cutoff threshold voltage (Vth), thereby causing the transistor 250 to operate as a resistor. Accordingly, the current through the transistor 250 is K*IREF, where K is a ratio of the size of the transistor 250 to the size of the transistor 210.

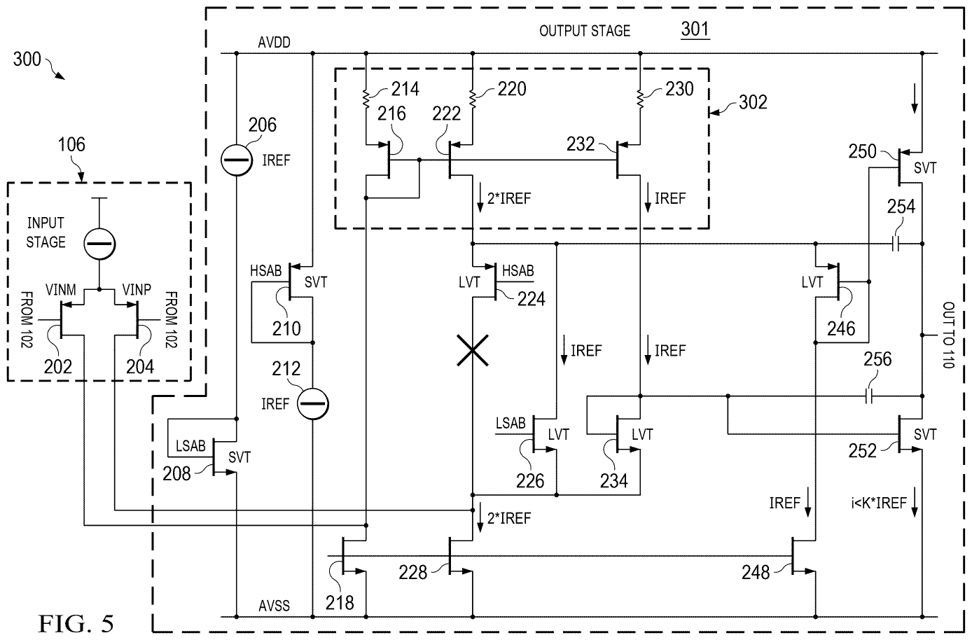

FIG. 5 illustrates the current flow through the output stage 301 of FIG. 3 during a sourcing state. Durin a sourcing state, the output stage 301 charges or provides AVDD to the output load. FIG. 5 includes all the components of FIG. 3. However, FIG. 5 could be described in conjunction with FIG. 2.

As shown in FIG. 5, during a sourcing state, the input stage 106 pulls the gate of the transistor 250 to a low voltage, thereby controlling the transistor 250 to operate as a current source to provide the required load current to the load. When the transistor 250 operates as a closed switch, AVDD is connected to the output load. Also, during the sourcing state, the voltage at the gate of the transistor 246 goes low, allowing IREF current to flow through the current terminals of the transistor 246 and the current terminals of the transistor 248. Because the transistor 224 has a fixed bias and the voltage at the first current terminal of the transistor 224 is also low during a sourcing state, the transistor 224 operates in cutoff mode operating as an open circuit and preventing current from flowing through the current terminals of the transistor 224. Accordingly, no current flows out from the second current terminal of the transistor 224. Thus, IREF flows across the current terminals of the transistor 226. As IREF flows across the current terminals of the transistor 226, the gate voltage of the transistor 252 lowers accordingly. For example, the gate voltage at the control terminal of the transistor 252 during the sourcing state is a lower voltage than the voltage at the control terminal of the transistor 252 during the quiescent state. Accordingly, because the gate voltage of the transistor 252 is lower, the current bias is lower during the quiescent state. Thus, the current across the current terminals of the transistor 252 is less than K*IREF and more than 0 during a sourcing state, which is consistent with the class AB output state operation.

As described above, some AB output stage amplifiers that are able to achieve operation using a near or below a one-volt power supply suffer from shoot-through current. Shoot-through current is uncontrolled large current that flows directly between the supply (AVDD) terminal and the common (AVSS) terminal through the output transistors 250, 252. During a transient or slew condition, the AB output stage increases the output voltage to match the increased input voltage after switching from a sinking state to a sourcing state. In power stages that have high shoot-through, during slew conditions, the node at the control terminal of the output low-side NMOS transistor 252 in such an AB output stage is a high impedance node. The control terminal of the output transistors 250, 252 could be rendered as a high impedance load momentarily leasing to shoot though conditions at the output stage 200, 300. Also, in such an AB output stage, there is a minimal pull up current through a pull up resistor during a slew condition. This combination causes the control terminal of the output low-side NMOS transistor to be driven strongly in the saturation (ON) state, thereby causing a large excess current to shoot-through the low-side NMOS transistor.

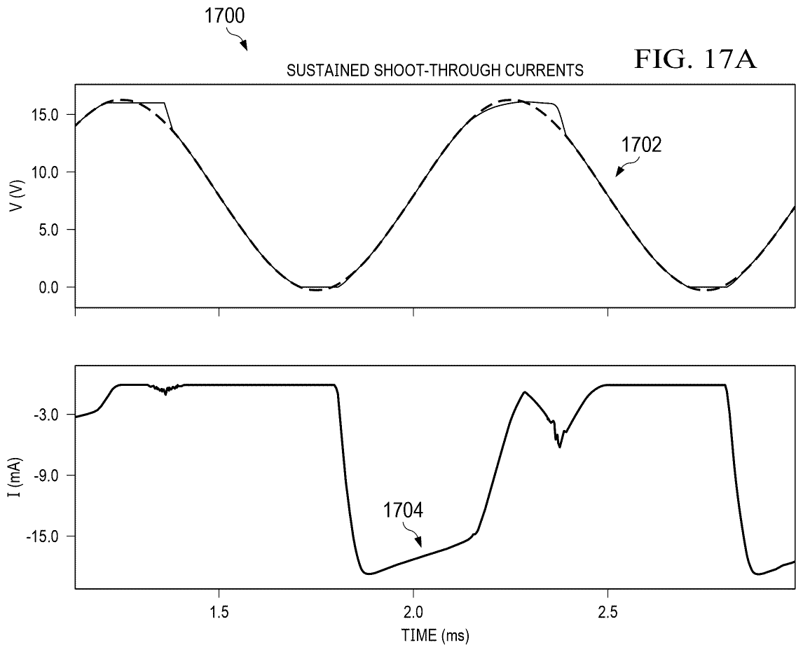

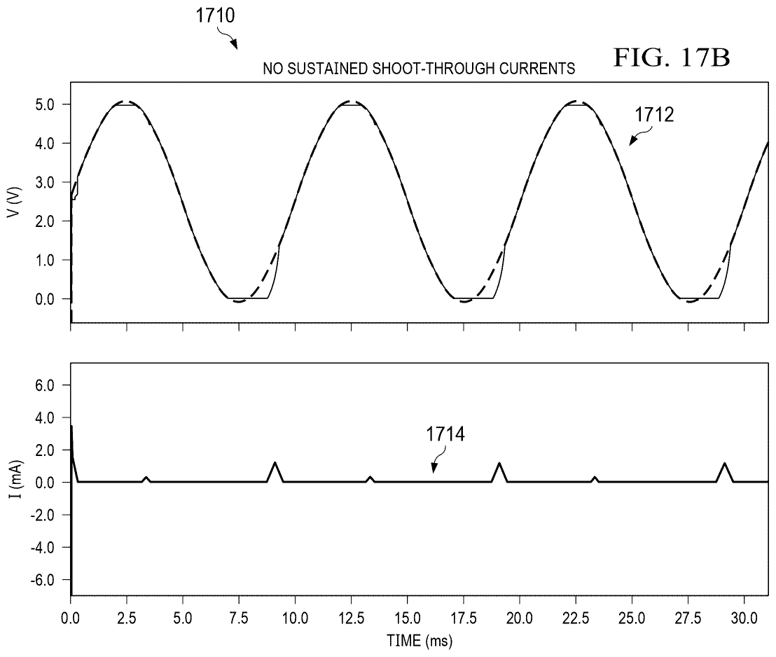

On the other hand, in the output stages 201, 301 of FIGS. 2-5, during a slew condition, a slew current flows from the supply, AVDD, terminal, across the current terminals of the transistors 250, through the capacitor 254, across the current terminals of the transistor 226, across the current terminals of the transistor 228 and to the common terminal, such as ground, AVSS, etc. For example, because, during a slew condition, the node voltage at the first current terminal of the transistor 226 is pulled low, current flows through the current terminals of the transistor 226. Because the transistor 248 is smaller than the transistor 228, at a ratio of 1:2, excess current is forced through the transistor 226, thereby regulating the voltage at the control terminal of the low side NMOS transistor 252 to prevent the transistor 252 from defining the current through the transistors 250, 252 and minimizing, or eliminating, shoot-through current. An example plot illustrating shoot through and how the AB output stage described herein mitigates shoot through is further described below in conjunction with FIGS. 17A and 17B.

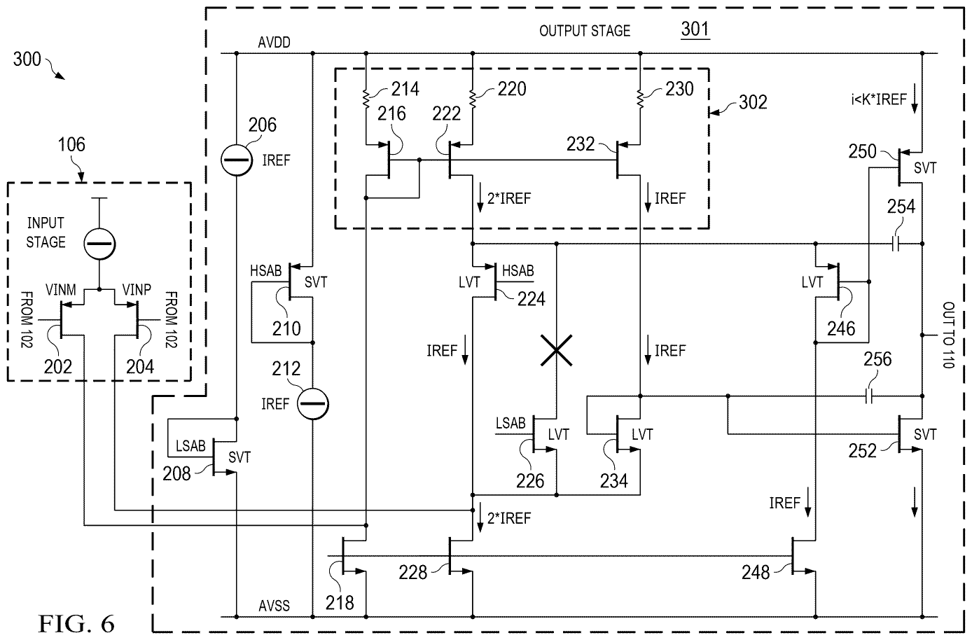

FIG. 6 illustrates the current flow through the output stage 301 of FIG. 3 during a sinking state. During a sinking state, the output stage 301 discharges or provides AVSS to the output load. FIG. 6 includes all the components of FIG. 3. However, FIG. 6 could be described in conjunction with FIG. 2.

As shown in FIG. 6, during a sinking state, the input stage 106 pulls the gate of the transistor 252 to a high voltage, thereby causing the transistor 252 to operate as a current source to provide the required load current to the load. Also, during the sinking state, the voltage at the gate of the transistor 234 goes high, allowing IREF current to flow through the current terminals of the transistor 234. Because the transistor 226 has a fixed bias and the voltage at the first current terminal of the transistor 226 is also high during a sinking state, the transistor 226 is in cutoff mode operating as an open circuit and preventing current from flowing through the current terminals of the transistor 226. Accordingly, no current flows out from the second current terminal of the transistor 226. Thus, IREF flows across the current terminals of the transistor 224. As IREF flows across the current terminals of the transistor 224, the gate voltage of the transistor 250 increases accordingly. For example, the gate voltage at the control terminal of the transistor 250 during the sinking state is a higher voltage than the voltage at the control terminal of the transistor 250 during the quiescent state. Accordingly, because the gate voltage of the transistor 250 is higher, the current bias is lower during the quiescent state. Thus, the current across the current terminals of the transistor 250 is less than K*IREF and more than 0 during a sinking state, which is consistent with the class AB output state operation.

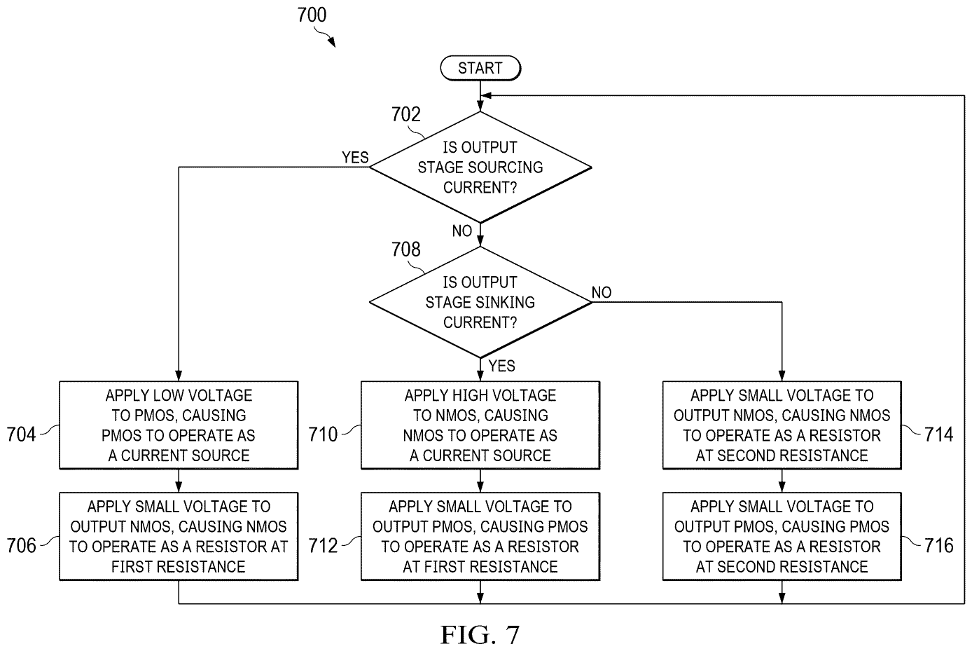

FIG. 7 is a flowchart representative of an example method or example operations 700 that may be at least one of executed, instantiated, or performed by the circuitry of FIGS. 1-3 to operate as a class AB amplifier. The example machine-readable instructions or the example operations 700 of FIG. 7 begin at block 702. At block 702, the output stage 201, 301 determines if the output stage is sourcing current based on the signal(s) from the input stage 106.

If the output stage 201, 301 determines that the output stage is not sourcing current (block 702: NO), control continues to block 708. If the output stage 201, 301 determines that the output stage is sourcing current (block 702: YES), a low voltage (0 V, for example) is applied to the control terminal of the transistor 250, causing the transistor 250 to operate a current source to provide the required load current to the load (block 704). At block 706, a small amount of voltage is applied to the control terminal of the transistor 252, causing the transistor 252 to operate as a resistor at a first resistance. The first resistance causes the current through the current terminals of the transistor 252 to be above 0 and less than K*IREF, consistent with class AB operation. The details of how the voltages are applied to the control terminals of the transistors 250, 252 is further described above in conjunction with FIG. 5.

At block 708, the output stage 201, 301 determines if the output stage is sinking current based on the signal(s) from the input stage 106. If the output stage 201, 301 determines that the output stage is not sinking current (block 708: NO), control continues to block 714 for the quiescent state operation. If the output stage 201, 301 determines that the output stage is sinking current (block 708: YES), a high voltage is applied to the control terminal of the transistor 252, causing the transistor 252 to operate as a current source to provide the required load current to the load (block 710). At block 712, a small amount of voltage is applied to the control terminal of the transistor 250, causing the transistor 250 to operate as a resistor at the first resistance. As described above, the first resistance causes the current through the current terminals of the transistor 250 to be above 0 and less than K*IREF, consistent with class AB operation. The details of how the voltages are applied to the control terminals of the transistors 250, 252 is further described above in conjunction with FIG. 6.

If the output stage 201, 301 determines that the output stage 201, 301 is not sinking or sourcing (blocks 702 and 708: NO), the output stage 201, 301 is in a quiescent state. At block 714, a small amount voltage is applied to the control terminal of the transistor 252, causing the transistor 252 to operate as a resistor with a second resistance (block 714). At block 716, a small amount of voltage is applied to the control terminal of the transistor 250, causing the transistor 250 to operate as a resistor at the second resistance. As described above, the second resistance causes the current through the current terminals of the transistor 250 and current through the current terminals of the transistor 252 to be equivalent to K*IREF, consistent with class AB operation. The details of how the voltages are applied to the control terminals of the transistors 250, 252 is further described above in conjunction with FIG. 4.

FIG. 8 is an example current graph 800 illustrating the class AB operation of the output stage 201, 301 of FIGS. 2 and 3 during sourcing, sinking, and quiescent states. The example graph 800 includes example low side current plots 802 corresponding to the amount of current through the current terminals of the transistor 252 of FIGS. 2-3 and example high side current plot 804 corresponding to the amount of current through the current terminals of the transistor 250 of FIGS. 2-3.

As shown in the example graph 800, during the sinking state, the low side current plot 802 is high at a high negative load current and decreases the closer the load current gets to 0. Also, during the sinking state, the high side current plot 804 is low (0.1 microamps, for example) but above zero, consistent with the stage AB operation. During the sourcing state, the high side current plot 804 is high at a high positive load current and decreases the closer the load current gets to 0. Also, during the sourcing state, the low side current plot 802 is low (0.1 microamps, for example) but above zero, consistent with stage AB operation. During the quiescent stage, both the low side current plot 802 and the high side current plot 804 are low (0.15 microamps, for example), but higher than (a) the high side current plot 804 during the sinking state and (b) the low side current plot 802 during the sourcing state, which is consistent with class AB operation.

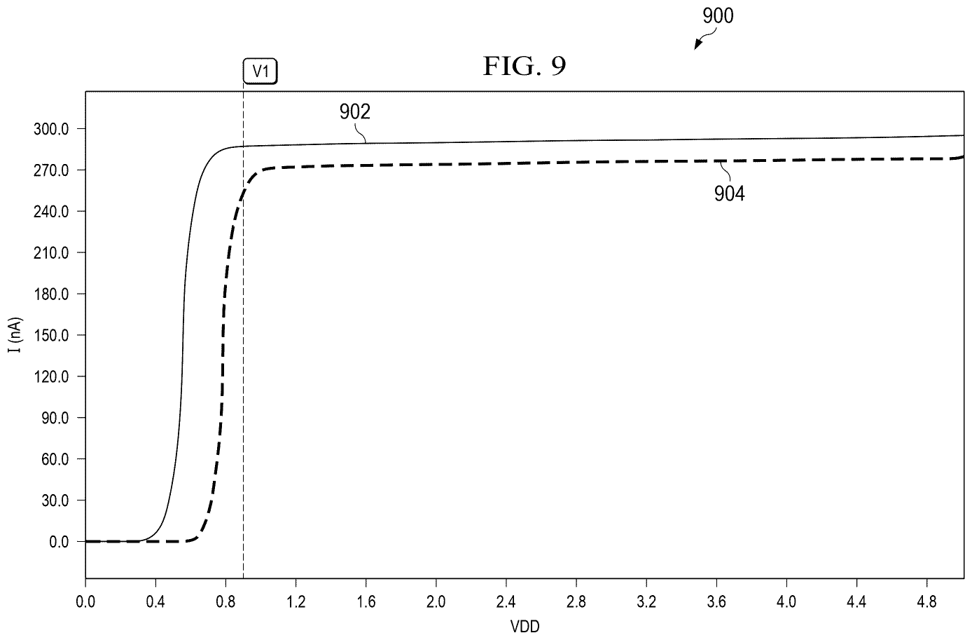

FIG. 9 is an example current graph 900 illustrating the class AB operation of the output stage 201, 301 of FIGS. 2 and 3 based on different supply voltages (VDD). The example graph 900 includes a first example quiescent current plot 802 for operation at 25 degrees Celsius and a second example quiescent current plot 802 for operation at −45 degrees Celsius. The quiescent current is the amount of current drawn by an integrated circuit in a no-load condition. The quiescent current needs to be above a threshold (200 nano amps, for example) for proper operation of the output stage.

As shown in the graph 900, the first quiescent current plot 902 corresponds to 0 quiescent current until the supply voltage VDD is at about 0.4 Volts (V) where the quiescent current increases with increased VDD. At about 0.7 V, the quiescent current plot 902 levels off at approximately 285 nano amps, sufficient for proper operation of the output stage 201, 301 of FIG. 2. The second quiescent current plot 904 corresponds to 0 quiescent current until the supply voltage VDD is about 0.7 V where the quiescent current increases with increased VDD. At about 0.9 V, the quiescent current ploy 904 levels off at approximately 270 nano amps, sufficient for proper operation of the output stage 201, 301.

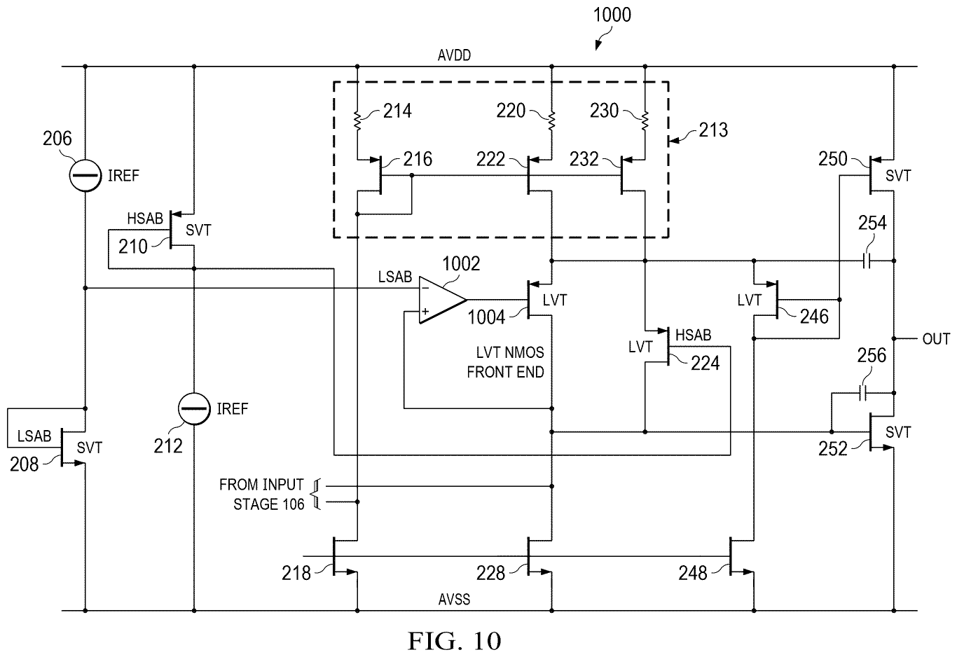

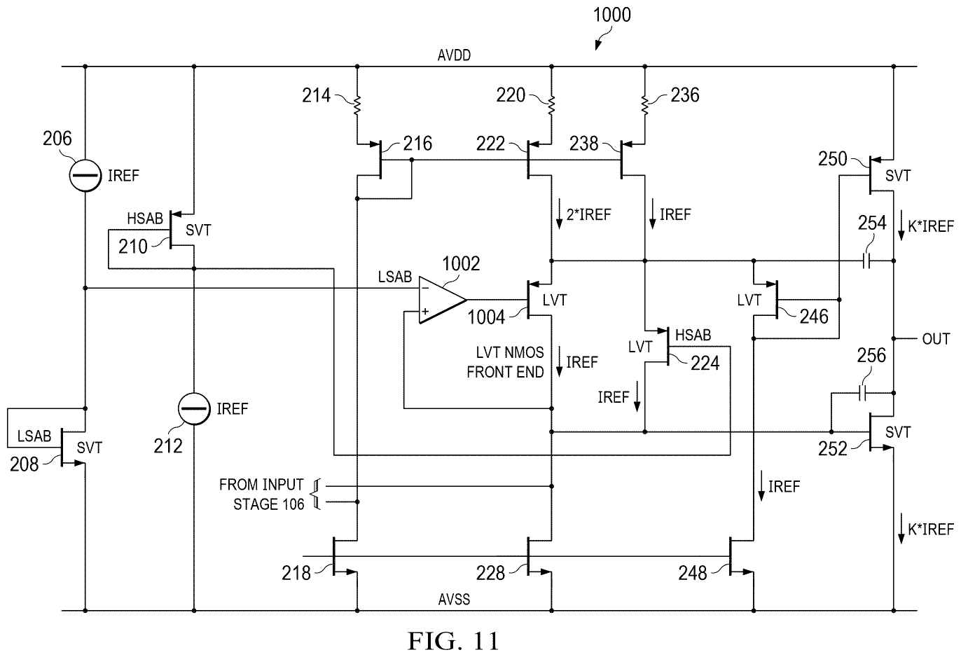

FIG. 10 includes example alternative circuitry to implement an example output stage 1000. The output stage 1000 can be used to implement the amplifier 104 of FIG. 1. As further described below, the output stage 1000 is structured to operate as a class AB/class A hybrid amplifier. For example, during in a quiescent state or a sourcing state, the output stage 1000 operates as a class AB amplifier and during a sinking state, the output stage 1000 operates as a class A amplifier. The example output stage 1000 includes the example current sources 206, 212, the example transistors 208, 210, 216, 218, 228, 232, 238, 240, 246, 248, 250, 252, the resistors 214, 230, 236, and the capacitors 254, 256 of FIG. 2. The output stage 1000 further includes an example amplifier 1002 and an example transistor 1004. The output stage 1000 replaces the transistors 224, 226, 234 for control of the low side transistor 252 with the amplifier 1002 and the transistor 1004. The output stage 1000 provides an alternative amplifier that can be used for low current densities. For example, for low currents, which may be a result of extreme temperatures, the current mirror operations for the amplifier 200 of FIGS. 2-5 may not hold up as well. For example, the Vgs of the LVT transistors of the amplifier 200 can drop very low in low current situations. A low Vgs introduces mismatch effects that can cause the amplifier 200 to not operate properly. The output stage 1000 can be used for low current applications. Also, although the output stage 1000 of FIG. 10 does not include the transistors 240, 238, 242, 244 and resistor 236 of the amplifier 200 of FIG. 2, the output stage 1000 could include the transistors 240, 238, 242, 244 and resistor 236 of the amplifier 200 of FIG. 2. Operation of the output stage 1000 of FIG. 10 is further described below in conjunction with FIGS. 11-13.

The amplifier 1002 of FIG. 10 is an amplifier that generates an output voltage that is an amplification of a difference in voltage between the two inputs of the amplifier 1002. The amplifier 1002 includes a first input (an inverting input), a second input (a non-inverting input), and an output. The first input of the sense amplifier is coupled to the first current terminal and the control terminal of the transistor 208 and the second terminal of the current source 206. The second input of the amplifier 1002 is coupled to the second current terminals of the transistors 1004, 240, the first current terminal of the transistor 228, the control terminal of the transistor 252, and the first terminal of the capacitor 256. The output of the amplifier 1002 is coupled to the control terminal of the transistor 1004. The amplifier 1002 provides a voltage that is an amplified difference between the two input voltages. The amplifier 1002 provides a voltage to force the voltage at the two inputs to be equal.

The transistor 1004 of FIG. 10 is controlled based on the output voltage of the amplifier 1002. The transistor includes a first current terminal (a source terminal), a second current terminal (a drain terminal), and a control terminal (a gate terminal). The first current terminal of the transistor 1004 is coupled to the second current terminals of the transistors 232, 238, the first current terminals of the transistors 1004, 240, 246, and the first terminal of the capacitor 254. The second current terminal of the transistor 1004 is coupled to the second input of the amplifier 1002, the second current terminal of the transistor 240, the first current terminal of the transistor 228, the control terminal of the transistor 252, and the first terminal of the capacitor 256. The control terminal of the transistor 1004 is coupled to the output of the amplifier 1002. The transistor 1004 is a PMOS. However, the transistor 1004 may be implemented by another type of transistor. If the voltage provided by the amplifier 1002 is above a threshold, the transistor 1004 blocks current from flowing to the first output. If the voltage provided by the amplifier 1002 is below the threshold, the transistor 1004 allows at least some current to flow out through the first output. The amount of current that the transistor 1004 allows may be based on the amount of voltage provided by the amplifier 1002. The transistor 1004 corresponds to a low voltage threshold (LVT) transistor.

The amplifier 1002 creates a second critical path. In the example of FIG. 10, the second critical path is from AVDD, across the current terminals of the transistor 222, from the first current terminal of the transistor 1004 to the control terminal of the transistor 1004, and across the current terminals of a transistor within the amplifier 1002 to AVSS. The source-to-gate voltage of the transistor 250 is approximately 0.7 Volts and the drain to source voltage drop across the transistor 222 is approximately 0.1 V and the voltage drop across the transistor within the amplifier 1002 is approximately 0.1 V. Thus, the minimum voltage for the output stage 1000 is 0.9 V. Thus, because the sum of the voltage drops along the first critical path is 0.9 V (e.g., less than 1 V) and the sum of the voltage drops across the second critical path is 0.9 V, the output stage 1000 of FIG. 10 can operate with a 1 V supply voltage or less than a 1 V supply voltage.

FIG. 11 illustrates the current flow through the output stage 1000 of FIG. 10 during a quiescent state. FIG. 11 includes all the components of FIG. 10.

As shown in FIG. 11, during a quiescent state, the transistor 248 is biased so that the current IREF current to flow into the first current source of the transistor 248. Also, during the quiescent state, the IREF current flows out from the second current terminal of the transistor 238.

Due to the size of the transistor 222, 2*IREF flows out from the second current terminal of the transistor 222, which is split between three paths. The first path is toward the transistor 246, the second path is toward the transistor 224, and the third path is toward the transistor 1004. Also, IREF from the second current terminal of the transistor 238 is pumped into the three paths. Accordingly, IREF flows toward the first current terminal of transistor 246, IREF flows toward the first current terminal of the transistor 1004, and IREF flows toward the first current terminal of the transistor 224. The amplifier 1002 generates an output voltage based on the feedback loop to ensure that the voltages at the two inputs of the amplifier 1002 are equal, thereby biasing the gate of the transistor 252 at a voltage between 0 and the cutoff threshold voltage (Vth), thereby causing the transistor 252 to operate as a resistor. Accordingly, the current through the transistor 252 is K*IREF, where K is a ratio of the size of the transistor 252 to the size of the transistor 208. The IREF current into the diode connected transistor 246 biases the gate of the transistor 250 at a voltage between 0 and the cutoff threshold voltage (Vth), thereby causing the transistor 250 to operate as a resistor. Accordingly, the current through the transistor 250 is K*IREF, where K is a ratio of the size of the transistor 250 to the size of the transistor 210.

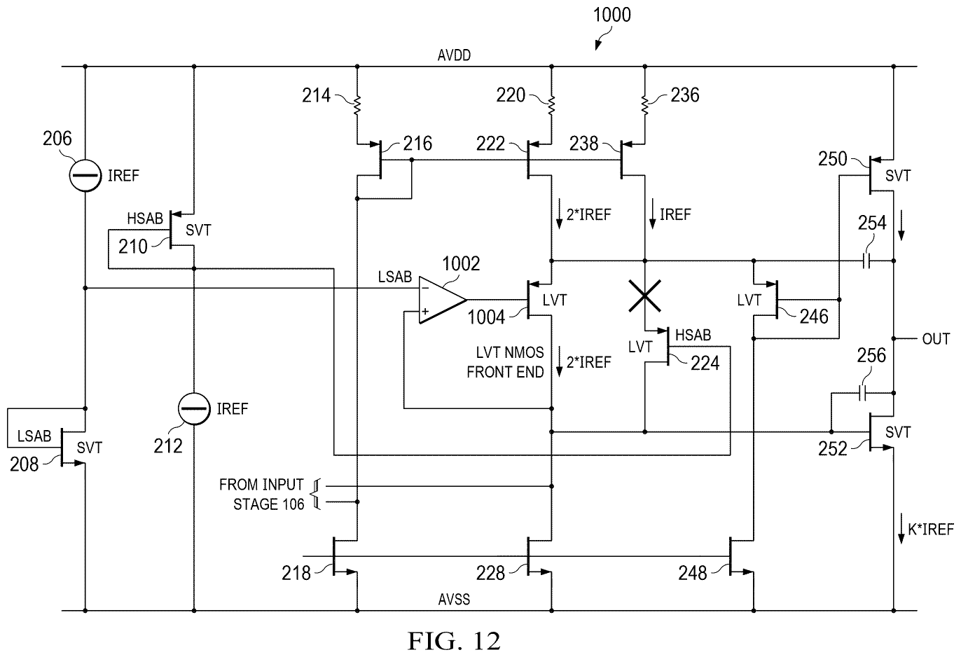

FIG. 12 illustrates the current flow through the output stage 1000 of FIG. 10 during a sourcing state. During a sourcing state, the output stage 1000 charges/provides AVDD to the output load. FIG. 12 includes all the components of FIG. 10.

As shown in FIG. 12, during a sourcing state, the input stage 106 pulls the gate of the transistor 250 to a low voltage, thereby causing the transistor 250 to operate as a current source to provide the required load current to the load. Also, during the sourcing state, the voltage at the gate of the transistor 246 goes low, allowing IREF current to flow through the current terminals of the transistor 246 and the current terminals of the transistor 248. Because the transistor 224 has a fixed bias and the voltage at the first current terminal of the transistor 224 is also low during a sourcing state, the transistor 224 is in cutoff mode operating as an open circuit and preventing current from flowing through the current terminals of the transistor 224. Accordingly, no current flows out from the second current terminal of the transistor 224. Thus, 2*IREF flows across the current terminals of the transistor 1004. As IREF flows across the current terminals of the transistor 1004, the amplifier 1002 regulates the output voltage based on the feedback loop, thereby causing the gate voltage of the transistor 252 to remain at the same resistance as during the quiescent state. Accordingly, because the gate voltage of the transistor 252 is the same as the quiescent state, the resistance of the transistor 252 is the same as the resistance of the transistor 252 during the quiescent state. Thus, the current across the current terminals of the transistor 252 is equivalent to K*IREF and during a sourcing state, which is consistent with the class A output state operation.

As described above, some AB output stage amplifiers that are able to achieve operation using a near or below a one-volt power supply suffer from shoot-through current. On the other hand, in the output stages 1000 of FIGS. 10-14, during a slew condition, a slew current flows from the supply, AVDD, terminal, across the current terminals of the transistors 250, through the capacitor 254, across the current terminals of the transistor 1004, across the current terminals of the transistor 228 and to the common terminal, such as ground, AVSS, etc. For example, because, during a slew condition, the node voltage at the first current terminal of the transistor 1004 is pulled low, current flows through the current terminals of the transistor 1004. Also, the amplifier 1002 adjusts the control of the transistor 1004 to regulate the voltage at the control terminal of the transistor 252 to prevent the transistor 252 from entering saturation operation and minimizing, or eliminating, shoot-through current. An example plot illustrating shoot through and how the AB output stage described herein mitigates shoot through is further described below in conjunction with FIGS. 17A and 17B.

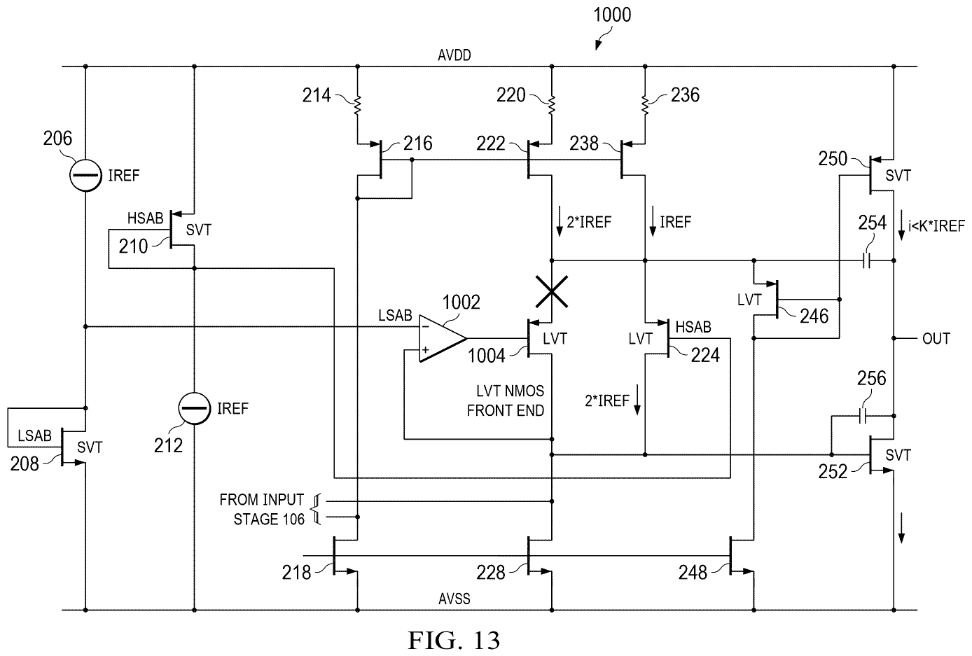

FIG. 13 illustrates the current flow through the output stage 1000 of FIG. 10 during a sinking state. During a sinking state, the output stage 1000 discharges/provides AVSS to the output load. FIG. 13 includes all the components of FIG. 10.

As shown in FIG. 13, during a sinking state, the input stage 106 pulls the gate of the transistor 252 to a high voltage, thereby causing the transistor 252 to operate as a current source to provide the required load current to the load. Also, during the sinking state, the first input of the amplifier 1002 rises and the amplifier 1002 pulls up the gate of the transistor 1004 to compensate/regulate based on the feedback loop. After the control terminal of the transistor 1004 reaches a threshold voltage, the transistor 1004 is in cutoff mode operating as an open circuit and preventing current from flowing through the current terminals of the transistor 1004. Accordingly, no current flows out from the second current terminal of the transistor 1004. Thus, 2*IREF flows across the current terminals of the transistor 224. As 2*IREF flows across the current terminals of the transistor 224, the gate voltage of the transistor 250 increases accordingly. For example, the gate voltage at the control terminal of the transistor 250 during the sinking state is a higher voltage than the voltage at the control terminal of the transistor 250 during the quiescent state. Accordingly, because the gate voltage of the transistor 250 is higher, the current bias is lower during the quiescent state. Thus, the current across the current terminals of the transistor 250 is less than K*IREF and more than 0 during a sinking state, which is consistent with the class AB output state operation.

FIGS. 12 and 13 illustrate that during sourcing, the amplifier 1002 loop is functioning to control low side control and during sinking, the amplifier loop naturally shuts off for high side control. Also, the use of the amplifier 1002 eliminates/reduces mismatching or mirroring errors of within transistors of the amplifier 1002. Also, regulation of the amplifier 1002 makes the biasing immune to mismatch between the transistor 246 and the transistor 224 in the quiescent state.

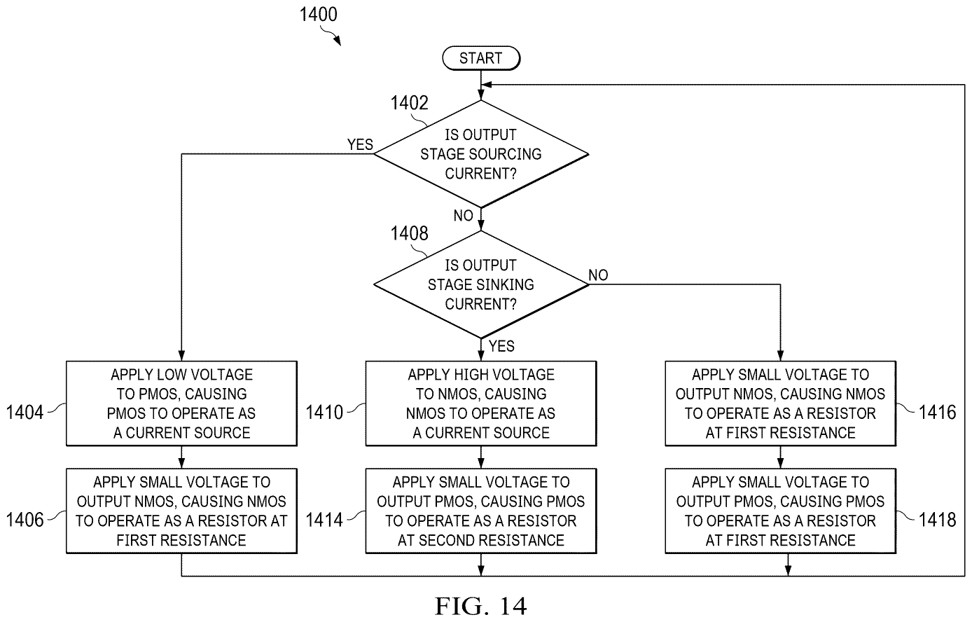

FIG. 14 is a flowchart representative of an example method or example operations 1400 that may be at least one of executed, instantiated, or performed by the circuitry of FIGS. 1-3 to operate as a hybrid class AB/class A amplifier. The example machine-readable instructions or the example operations 1400 of FIG. 14 begin at block 1402. At block 1402, the output stage 1000 determines if the output stage is sourcing current based on the signal(s) from the input stage 106.

If the output stage 1000 determines that the output stage is not sourcing current (block 1402: NO), control continues to block 1408. If the output stage 1000 determines that the output stage is sourcing current (block 1402: YES), a low voltage (0 V) is applied to the control terminal of the transistor 250, causing the transistor 250 to operate as a current source to provide the required load current to the load (block 1404). At block 1406, a small amount of voltage is applied to the control terminal of the transistor 252, causing the transistor 252 to operate as a resistor at a first resistance. The first resistance causes the current through the current terminals of the transistor 252 to be equivalent to K*IREF, consistent with class A operation. The details of how the voltages are applied to the control terminals of the transistors 250, 252 is further described above in conjunction with FIG. 12.

At block 1408, the output stage 1000 determines if the output stage is sinking current based on the signal(s) from the input stage 106. If the output stage 1000 determines that the output stage is not sinking current (block 1408: NO), control continues to block 1414 for the quiescent state operation. If the output stage 1000 determines that the output stage is sinking current (block 1408: YES), a high voltage is applied to the control terminal of the transistor 252, causing the transistor 252 to operate as a current source to provide the required load current to the load (block 1410). At block 1412, a small amount of voltage is applied to the control terminal of the transistor 250, causing the transistor 250 to operate as a resistor at a second resistance. The second resistance causes the current through the current terminals of the transistor 250 to be above 0 and less than K*IREF, consistent with class AB operation. The details of how the voltages are applied to the control terminals of the transistors 250, 252 is further described above in conjunction with FIG. 13.

If the output stage 1000 determines that the output stage 1000 is not sinking or sourcing (blocks 1402 and 1408: NO), the output stage 1000 is in a quiescent state. At block 1414, a small amount voltage is applied to the control terminal of the transistor 252, causing the transistor 252 to operate as a resistor with the first resistance (block 1416). At block 1416, a small amount of voltage is applied to the control terminal of the transistor 250, causing the transistor 250 to operate as a resistor at the first resistance. As described above, the first resistance causes the current through the current terminals of the transistor 250 and current through the current terminals of the transistor 252 to be equivalent to K*IREF, consistent with class AB operation. The details of how the voltages are applied to the control terminals of the transistors 250, 252 is further described above in conjunction with FIG. 11.

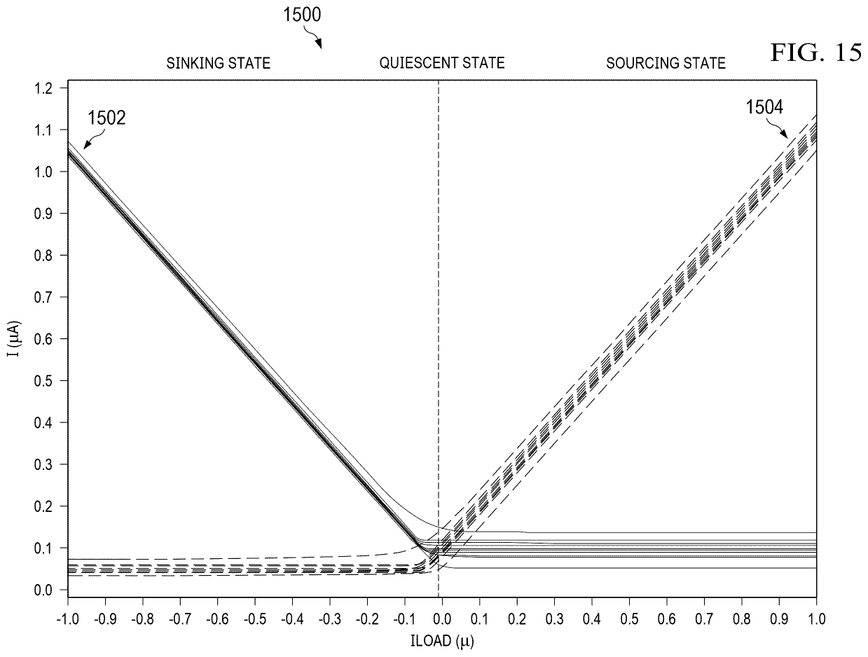

FIG. 15 is an example current graph 1500 illustrating the class AB operation of the output stage 1000 of FIGS. 2 and 3 during sourcing, sinking, and quiescent states. The example graph 1500 includes example low side current plots 1502 corresponding to the amount of current through the current terminals of the transistor 252 of FIG. 10 and example high side current plot 1504 corresponding to the amount of current through the current terminals of the transistor 250 of FIG. 10.

As shown in the example graph 1500, during the sinking state, the low side current plot 1502 is high at a high negative load current and decreases the closer the load current gets to 0. Also, during the sinking state, the high side current plot 1504 is low (0.1 microamps, for example) but above zero, consistent with the stage AB operation. During the sourcing state, the high side current plot 1504 is high at a high positive load current and decreases the closer the load current gets to 0. Also, during the sourcing state, the low side current plot 1502 is low (0.15 microamps, for example) which is the same as the quiescent stage, consistent with stage A operation. During the quiescent stage, both the low side current plot 1502 and the high side current plot 1504 is low (0.15 microamps, for example), but higher than (a) the high side current plot 1504 during the sinking state and (b) the low side current plot 1502 during the sourcing state, which is consistent with class AB operation.

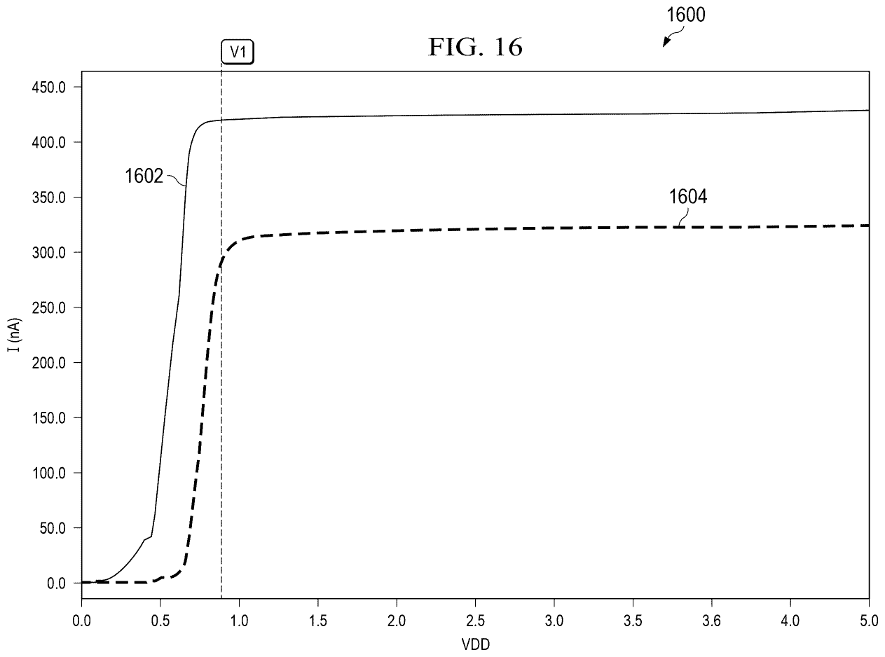

FIG. 16 is an example current graph 1600 illustrating the class AB operation of the output stage 1000 of FIGS. 2 and 3 based on different supply voltages (VDD). The example graph 1600 includes a first example quiescent current plot 1502 for operation at 25 degrees Celsius and a second example quiescent current plot 1502 for operation at −45 degrees Celsius. The quiescent current is the amount of current drawn by an integrated circuit in a no-load condition. The quiescent current needs to be above a threshold (200 nano amps, for example) for proper operation of the output stage.

As shown in the graph 1600, the first quiescent current plot 1602 corresponds to 0 quiescent current until the supply voltage VDD is at about 0.4 Volts (V) where the quiescent current increases with increased VDD. At about 0.7 V, the quiescent current plot 1602 levels off at approximately 425 nano amps, sufficient for proper operation of the output stage 1000 of FIG. 2. The second quiescent current plot 1604 corresponds to 0 quiescent current until the supply voltage VDD is about 0.7 V where the quiescent current increase with increased VDD. At about 0.9 V, the quiescent current ploy 1604 levels off at approximately 320 nano amps, sufficient for proper operation of the output stage 1000.

FIGS. 17A and 17B illustrate a comparison of a first graph 1700 to a second graph 1710. The first graph 1700 includes an example output voltage plot 1702 and an example output current plot 1704 of a class AB output stage that does not correspond to examples described herein. The second graph 1710 includes an output voltage plot 1712 and an example output current plot 1714 of the class AB output stages 201, 301, 1100 of FIGS. 2-6 and 10-13.

As shown in the first graph 1700, the output voltage plots 1702, 1712 are sinusoidal. As the output voltage plots 1702, 1712 are decreasing, the corresponding class AB output stage is sinking and as the output voltage plots 1702, 1712 are increasing, the corresponding class AB output stage is sourcing. As the class AB output stage that does not correspond to examples described herein is sourcing, the output current 1704 experiences significant deformation due to sustained shoot-through currents. However, as the class AB output stage 201, 301, 1100 of FIGS. 2-6 and 10-13 is sourcing, the output current plot 1714 is much less deformed due to limited shoot-through currents. Accordingly, examples described herein result in a more controlled current flow that provides protection to the components of the class AB amplifier or the components of the load.

One or more example manners of implementing the output stage 108 of FIG. 1 is illustrated in FIGS. 2-6 and 10-13. However, one or more of the elements, processes or devices illustrated in FIGS. 2-6 and 10-13 may be combined, divided, re-arranged, omitted, eliminated, or implemented in any other way.

Further, the output stage 108 could be implemented by one or more analog or digital circuit(s), logic circuits, programmable processor(s), programmable controller(s), graphics processing unit(s) (GPU(s)), digital signal processor(s) (DSP(s)), application specific integrated circuit(s) (ASIC(s)), programmable logic device(s) (PLD(s)) or field programmable logic device(s) (FPLD(s)).

Although certain example methods, apparatus and articles of manufacture have been described herein, the scope of coverage of this patent is not limited thereto. On the contrary, this patent covers all methods, apparatus and articles of manufacture fairly falling within the scope of the claims of this patent.

Descriptors “first,” “second,” “third,” etc. are used herein to identify multiple elements or components which may be referred to separately. Unless otherwise specified or known based on their context of use, such descriptors do not impute any meaning of priority, physical order, or arrangement in a list, or ordering in time but are merely used as labels for referring to multiple elements or components separately for ease of understanding the described examples. In some examples, the descriptor “first” may be used to refer to an element in the detailed description, while the same element may be referred to in a claim with a different descriptor such as “second” or “third.” In such instances, such descriptors are used merely for ease of referencing multiple elements or components.

In the description and in the claims, the terms “including” and “having,” and variants thereof are to be inclusive in a manner similar to the term “comprising” unless otherwise noted. Unless otherwise stated, “about,” “approximately,” or “substantially” preceding a value means +/−10 percent of the stated value. In another example, “about,” “approximately,” or “substantially” preceding a value means +/−5 percent of the stated value. IN another example, “about,” “approximately,” or “substantially” preceding a value means +/−1 percent of the stated value.

The terms “couple,” “coupled,” “couples,” and variants thereof, as used herein, may cover connections, communications, or signal paths that enable a functional relationship consistent with this description. For example, if device A generates a signal to control device B to perform an action, if a first example device A is coupled to device B, or if a second example device A is coupled to device B through intervening component C if intervening component C does not substantially alter the functional relationship between device A and device B, such that device B is controlled by device A via the control signal generated by device A. Moreover, the terms “couple,” “coupled”, “couples”, or variants thereof, includes an indirect or direct electrical or mechanical connection.

A device that is “configured to” perform a task or function may be configured (e.g., at least one of programmed or hardwired) at a time of manufacturing by a manufacturer to perform the function or may be configurable (or re-configurable) by a user after manufacturing to perform the function or other additional or alternative functions. The configuring may be through at least one firmware or software programming of the device, through a construction or layout of hardware components and interconnections of the device, or a combination thereof.

Although not all separately labeled in the FIGS. 2-6 and 10-13, components or elements of systems and circuits illustrated therein have one or more conductors or terminus that allow signals into or out of the components or elements. The conductors or terminus (or parts thereof) may be referred to herein as pins, pads, terminals (including input terminals, output terminals, reference terminals, and ground terminals, for instance), inputs, outputs, nodes, and interconnects.

As used herein, a “terminal” of a component, device, system, circuit, integrated circuit, or other electronic or semiconductor component, generally refers to a conductor such as a wire, trace, pin, pad, or other connector or interconnect that enables the component, device, system, etc., to electrically or mechanically connect to another component, device, system, etc. A terminal may be used, for instance, to receive or provide analog or digital electrical signals (or simply signals) or to electrically connect to a common or ground reference. Accordingly, an input terminal or input is used to receive a signal from another component, device, system, etc. An output terminal or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on particular circuitry or system topology, there may be more or fewer terminals and nodes. However, in some instances, “terminal,” “node,” “interconnect,” “pad,” and “pin” may be used interchangeably.

The term “or” as used, for example, in a form such as A, B, or C refers to any combination or subset of A, B, C such as (1) A alone, (2) B alone, (3) C alone, (4) A with B, (5) A with C, (6) B with C, or (7) A with B and with C.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Example methods, apparatus, systems, and articles of manufacture corresponding to low voltage output stage designs for amplifiers are described herein. Further examples and combinations thereof include the following: Example 1 includes an apparatus comprising an input stage having a first output and a second output, current mirror circuitry having a first terminal and a second terminal, the first terminal coupled to the first output of the input stage, a first transistor having a first current terminal and a second current terminal, the first current terminal of the first transistor coupled to the second terminal of the current mirror circuitry, the second current terminal of the first transistor coupled to the second output of the input stage, a second transistor having a first current terminal, a second current terminal, and a control terminal, the first current terminal of the second transistor coupled to the first current terminal of the first transistor and the second terminal of the current mirror circuitry, the second current terminal of the second transistor coupled to the control terminal of the second transistor, a third transistor having a first current terminal and a second current terminal, the first current terminal of the third transistor coupled to the second current terminal and the control terminal of the second transistor, the second current terminal of the third transistor coupled to a common terminal, a fourth transistor having a first current terminal, a second current terminal, and a control terminal, the first current terminal of the fourth transistor coupled to a supply terminal, the control terminal of the fourth transistor coupled to the first current terminal and the control terminal of the second transistor and the first current terminal of the third transistor, and a fifth transistor having a first current terminal and a second current terminal, the first current terminal of the fifth transistor coupled to the second current terminal of the fourth transistor, the second current terminal of the fifth transistor coupled to the common terminal.

Example 2 includes the apparatus of example 1, wherein the first transistor has a control terminal, further including a current source having a first terminal and a second terminal, the second terminal of the current source coupled to the common terminal, and a sixth transistor having a first current terminal, a second current terminal, and a control terminal, the first current terminal of the sixth transistor coupled to the supply terminal, the second current terminal of the sixth transistor coupled to the control terminal of the first transistor, the control terminal of the sixth transistor and the first terminal of the current source.

Example 3 includes the apparatus of example 1, wherein the current mirror circuitry has a third terminal and a fourth terminal, the first terminal and the fourth terminal of the current mirror circuitry coupled to the supply terminal.

Example 4 includes the apparatus of example 1, further including a sixth transistor having a first current terminal and a second current terminal, the first current terminal of the sixth transistor coupled to the second current terminal of the sixth transistor and the second output of the input stage, the second current terminal of the sixth transistor coupled to the common terminal.

Example 5 includes the apparatus of example 4, further including a seventh transistor having a first current terminal and a second current terminal, the first current terminal of the seventh transistor coupled to the first terminal of the current mirror circuitry and the second output of the input stage, the second current terminal of the seventh transistor coupled to the common terminal.

Example 6 includes the apparatus of example 5, wherein the third transistor has a control terminal, the sixth transistor has a control terminal, and the seventh transistor has a control terminal, the control terminal of the third transistor coupled to the control terminal of the sixth transistor and the control terminal of the seventh transistor.

Example 7 includes the apparatus of example 1, further including a capacitor having a first terminal and a second terminal, the first terminal of the capacitor coupled to the first current terminals of the first and second transistors, the second terminal of the capacitor coupled to the second current terminal of the fourth transistor.

Example 8 includes the apparatus of example 1, wherein the first, second, and fourth transistors are p-channel metal oxide semiconductor field effect transistors and the third transistor is an n-channel metal oxide semiconductor field effect transistor.

Example 9 includes an apparatus comprising an input stage having a first output and a second output, current mirror circuitry having a first terminal, a second terminal, and a third terminal, the first terminal coupled to the first output of the input stage, a first transistor having a first current terminal and a second current terminal, the first current terminal of the first transistor coupled to the second terminal of the current mirror circuitry, the second current terminal of the first transistor coupled to the second output of the input stage, a second transistor having a first current terminal, a second current terminal, and a control terminal, the first current terminal of the second transistor coupled to the third terminal of the current mirror circuitry and the control terminal of the second transistor, the second current terminal of the second transistor coupled to the second current terminal of the first transistor and the second output of the input stage, a third transistor having a first current terminal and a second current terminal, the first current terminal of the third transistor coupled to the second current terminals of the first and second transistors and the second output of the input stage, the second current terminal of the third transistor coupled to a common terminal, a fourth transistor having a first current terminal, a second current terminal and a control terminal, the second current terminal of the fourth transistor coupled to the common terminal, the control terminal of the fourth transistor coupled to the first current terminal and the control terminal of the second transistor and the third terminal of the current mirror circuitry, and a fifth transistor having a first current terminal and a second current terminal, the first current terminal of the fifth transistor coupled to a supply terminal, the second current terminal of the fifth transistor coupled to the first current terminal of the fourth transistor.

Example 10 includes the apparatus of example 9, wherein the first transistor has a control terminal, further including a current source having a first terminal and a second terminal, the first terminal of the current source coupled to a supply terminal, and a sixth transistor having a first current terminal, a second current terminal, and a control terminal, the first current terminal of the sixth transistor coupled to the second terminal of the current source, the control terminal of the sixth transistor, and the control terminal of the first transistor, the second current terminal of the sixth transistor coupled to the common terminal.

Example 11 includes the apparatus of example 9, wherein the current mirror circuitry has a fourth terminal, a fifth terminal, and a sixth terminal, the fourth terminal, the fifth terminal, and the sixth terminal of the current mirror circuitry coupled to a supply terminal.

Example 12 includes the apparatus of example 9, further including a sixth transistor having a first current terminal and a second current terminal, the first current terminal of the sixth transistor coupled to the first terminal of the current mirror circuitry and the second output of the input stage, the second current terminal of the sixth transistor coupled to the common terminal.

Example 13 includes the apparatus of example 12, wherein the third transistor has a control terminal and the sixth transistor has a control terminal, the control terminal of the third transistor coupled to the control terminal of the sixth transistor.

Example 14 includes the apparatus of example 9, further including a capacitor having a first terminal and a second terminal, the first terminal of the capacitor coupled to the first current terminal and the control terminal of the second transistor 234, the third terminal of the current mirror circuitry, and the control terminal of the fourth transistor, the second terminal of the capacitor coupled to the first current terminal of the fourth transistor.

Example 15 includes the apparatus of example 9, wherein the first, second, third, and fourth transistors are n-channel metal oxide semiconductor field effect transistors.

Example 16 includes an apparatus comprising an input stage having a first output and a second output, current mirror circuitry having a first terminal, a second terminal, and a third terminal, the first terminal coupled to the first output of the input stage, a first transistor having a first current terminal, a second current terminal, and a control terminal, the first current terminal of the first transistor coupled to the second terminal and the third terminal of the current mirror circuitry, the second current terminal of the first transistor coupled to the second output of the input stage, an amplifier having a first input, a second input, and an output, the second input of the amplifier coupled to the second current terminal of the first transistor, the output of the amplifier coupled to the control terminal of the first transistor, a second transistor having a first current terminal and a second current terminal, the first current terminal of the second transistor coupled to the second current terminal of the first transistor, the second input of the amplifier, and the second output of the input stage, the second current terminal of the second transistor coupled to a common terminal, a third transistor having a first current terminal, a second current terminal and a control terminal, the second current terminal of the third transistor coupled to the common terminal, the control terminal of the third transistor coupled to the second current terminal of the first transistor, the second input of the amplifier, the first current terminal of the second transistor and the second output of the input stage, and a fourth transistor having a first current terminal and a second current terminal, the first current terminal of the fourth transistor coupled to a supply terminal, the second current terminal of the fourth transistor coupled to the first current terminal of the third transistor.

Example 17 includes the apparatus of example 16, wherein the first transistor has a control terminal, further including a current source having a first terminal and a second terminal, the first terminal of the current source coupled to a supply terminal, and a fifth transistor having a first current terminal, a second current terminal, and a control terminal, the first current terminal of the fifth transistor coupled to the second terminal of the current source, the control terminal of the fifth transistor, and the first input of the amplifier, the second current terminal of the fifth transistor coupled to the common terminal.

Example 18 includes the apparatus of example 16, wherein the first input of the amplifier is a non-inverting input and the second input of the amplifier is an inverting input.

Example 19 includes the apparatus of example 16, further including a capacitor having a first terminal and a second terminal, the first terminal of the capacitor coupled to the second current terminal of the first transistor, the second input of the amplifier, the first current terminal of the second transistor, and the control terminal of the third transistor.

Example 20 includes the apparatus of example 16, wherein the first and fourth transistors are a p-channel metal oxide semiconductor field effect transistor and the second and transistors are n-channel metal oxide semiconductor field effect transistors.

From the foregoing, it is appreciated that example systems, apparatus, articles of manufacture, and methods have been described corresponding to low voltage output stage designs for amplifiers. Described systems, apparatus, articles of manufacture, and methods result in an output stage that is operable at a sub 1 V power supply while minimizing unwanted shoot-through current. Thus, described systems, apparatus, articles of manufacture, and methods are accordingly directed to one or more improvement(s) in the operation of a machine such as a computer or other electronic device.

Modifications are possible in the examples described, and other examples are possible, within the scope of the claims.

What is claimed is:

1. An apparatus comprising:
an input stage having a first output and a second output;
current mirror circuitry having a first terminal and a second terminal, the first terminal coupled to the first output of the input stage;
a first transistor having a first current terminal and a second current terminal, the first current terminal of the first transistor coupled to the second terminal of the current mirror circuitry, the second current terminal of the first transistor coupled to the second output of the input stage;
a second transistor having a first current terminal, a second current terminal, and a control terminal, the first current terminal of the second transistor coupled to the first current terminal of the first transistor and the second terminal of the current mirror circuitry, the second current terminal of the second transistor coupled to the control terminal of the second transistor;
a third transistor having a first current terminal and a second current terminal, the first current terminal of the third transistor coupled to the second current terminal and the control terminal of the second transistor, the second current terminal of the third transistor coupled to a common terminal;
a fourth transistor having a first current terminal, a second current terminal, and a control terminal, the first current terminal of the fourth transistor coupled to a supply terminal, the control terminal of the fourth transistor coupled to the first current terminal and the control terminal of the second transistor and the first current terminal of the third transistor; and
a fifth transistor having a first current terminal and a second current terminal, the first current terminal of the fifth transistor coupled to the second current terminal of the fourth transistor, the second current terminal of the fifth transistor coupled to the common terminal.

2. The apparatus of claim 1, wherein the first transistor has a control terminal, further including:
a current source having a first terminal and a second terminal, the second terminal of the current source coupled to the common terminal; and
a sixth transistor having a first current terminal, a second current terminal, and a control terminal, the first current terminal of the sixth transistor coupled to the supply terminal, the second current terminal of the sixth transistor coupled to the control terminal of the first transistor, the control terminal of the sixth transistor and the first terminal of the current source.

3. The apparatus of claim 1, wherein the current mirror circuitry has a third terminal and a fourth terminal, the first terminal and the fourth terminal of the current mirror circuitry coupled to the supply terminal.

4. The apparatus of claim 1, further including a sixth transistor having a first current terminal and a second current terminal, the first current terminal of the sixth transistor coupled to the second current terminal of the sixth transistor and the second output of the input stage, the second current terminal of the sixth transistor coupled to the common terminal.

5. The apparatus of claim 4, further including a seventh transistor having a first current terminal and a second current terminal, the first current terminal of the seventh transistor coupled to the first terminal of the current mirror circuitry and the second output of the input stage, the second current terminal of the seventh transistor coupled to the common terminal.

6. The apparatus of claim 5, wherein the third transistor has a control terminal, the sixth transistor has a control terminal, and the seventh transistor has a control terminal, the control terminal of the third transistor coupled to the control terminal of the sixth transistor and the control terminal of the seventh transistor.

7. The apparatus of claim 1, further including a capacitor having a first terminal and a second terminal, the first terminal of the capacitor coupled to the first current terminals of the first and second transistors, the second terminal of the capacitor coupled to the second current terminal of the fourth transistor.

8. The apparatus of claim 1, wherein the first, second, and fourth transistors are p-channel metal oxide semiconductor field effect transistors and the third transistor is an n-channel metal oxide semiconductor field effect transistor.

9. An apparatus comprising:
an input stage having a first output and a second output;
current mirror circuitry having a first terminal, a second terminal, and a third terminal, the first terminal coupled to the first output of the input stage;
a first transistor having a first current terminal and a second current terminal, the first current terminal of the first transistor coupled to the second terminal of the current mirror circuitry, the second current terminal of the first transistor coupled to the second output of the input stage;
a second transistor having a first current terminal, a second current terminal, and a control terminal, the first current terminal of the second transistor coupled to the third terminal of the current mirror circuitry and the control terminal of the second transistor, the second current terminal of the second transistor coupled to the second current terminal of the first transistor and the second output of the input stage;
a third transistor having a first current terminal and a second current terminal, the first current terminal of the third transistor coupled to the second current terminals of the first and second transistors and the second output of the input stage, the second current terminal of the third transistor coupled to a common terminal;
a fourth transistor having a first current terminal, a second current terminal and a control terminal, the second current terminal of the fourth transistor coupled to the common terminal, the control terminal of the fourth transistor coupled to the first current terminal and the control terminal of the second transistor and the third terminal of the current mirror circuitry; and
a fifth transistor having a first current terminal and a second current terminal, the first current terminal of the fifth transistor coupled to a supply terminal, the second current terminal of the fifth transistor coupled to the first current terminal of the fourth transistor.

10. The apparatus of claim 9, wherein the first transistor has a control terminal, further including:
a current source having a first terminal and a second terminal, the first terminal of the current source coupled to a supply terminal; and
a sixth transistor having a first current terminal, a second current terminal, and a control terminal, the first current terminal of the sixth transistor coupled to the second terminal of the current source, the control terminal of the sixth transistor, and the control terminal of the first transistor, the second current terminal of the sixth transistor coupled to the common terminal.

11. The apparatus of claim 9, wherein the current mirror circuitry has a fourth terminal, a fifth terminal, and a sixth terminal, the fourth terminal, the fifth terminal, and the sixth terminal of the current mirror circuitry coupled to a supply terminal.

12. The apparatus of claim 9, further including a sixth transistor having a first current terminal and a second current terminal, the first current terminal of the sixth transistor coupled to the first terminal of the current mirror circuitry and the second output of the input stage, the second current terminal of the sixth transistor coupled to the common terminal.

13. The apparatus of claim 12, wherein the third transistor has a control terminal and the sixth transistor has a control terminal, the control terminal of the third transistor coupled to the control terminal of the sixth transistor.

14. The apparatus of claim 9, further including a capacitor having a first terminal and a second terminal, the first terminal of the capacitor coupled to the first current terminal and the control terminal of the second transistor 234, the third terminal of the current mirror circuitry, and the control terminal of the fourth transistor, the second terminal of the capacitor coupled to the first current terminal of the fourth transistor.

15. The apparatus of claim 9, wherein the first, second, third, and fourth transistors are n-channel metal oxide semiconductor field effect transistors.

16. An apparatus comprising:
an input stage having a first output and a second output;
current mirror circuitry having a first terminal, a second terminal, and a third terminal, the first terminal coupled to the first output of the input stage;
a first transistor having a first current terminal, a second current terminal, and a control terminal, the first current terminal of the first transistor coupled to the second terminal and the third terminal of the current mirror circuitry, the second current terminal of the first transistor coupled to the second output of the input stage;
an amplifier having a first input, a second input, and an output, the second input of the amplifier coupled to the second current terminal of the first transistor, the output of the amplifier coupled to the control terminal of the first transistor;
a second transistor having a first current terminal and a second current terminal, the first current terminal of the second transistor coupled to the second current terminal of the first transistor, the second input of the amplifier, and the second output of the input stage, the second current terminal of the second transistor coupled to a common terminal;
a third transistor having a first current terminal, a second current terminal and a control terminal, the second current terminal of the third transistor coupled to the common terminal, the control terminal of the third transistor coupled to the second current terminal of the first transistor, the second input of the amplifier, the first current terminal of the second transistor and the second output of the input stage; and
a fourth transistor having a first current terminal and a second current terminal, the first current terminal of the fourth transistor coupled to a supply terminal, the second current terminal of the fourth transistor coupled to the first current terminal of the third transistor.

17. The apparatus of claim 16, wherein the first transistor has a control terminal, further including:
a current source having a first terminal and a second terminal, the first terminal of the current source coupled to a supply terminal; and
a fifth transistor having a first current terminal, a second current terminal, and a control terminal, the first current terminal of the fifth transistor coupled to the second terminal of the current source, the control terminal of the fifth transistor, and the first input of the amplifier, the second current terminal of the fifth transistor coupled to the common terminal.

18. The apparatus of claim 16, wherein the first input of the amplifier is a non-inverting input and the second input of the amplifier is an inverting input.

19. The apparatus of claim 16, further including a capacitor having a first terminal and a second terminal, the first terminal of the capacitor coupled to the second current terminal of the first transistor, the second input of the amplifier, the first current terminal of the second transistor, and the control terminal of the third transistor.

20. The apparatus of claim 16, wherein the first and fourth transistors are a p-channel metal oxide semiconductor field effect transistor and the second and transistors are n-channel metal oxide semiconductor field effect transistors.
